(19) United States
(12) Patent Application Publication
(10) Pub. No.: US 2023/0191761 A1
(43) Pub. Date: Jun. 22, 2023

(54) DIELECTRIC SUBSTRATE AND METHOD OF FORMING THE SAME

(71) Applicant: SAINT-GOBAIN PERFORMANCE PLASTICS CORPORATION, Solon, OH (US)

(72) Inventors: Jennifer ADAMCHUK, Marlborough, MA (US); Dale Thomas, Rochdale (GB); Meghann White, Bedford, NH (US); Sethumadhavan Ravichandran, Shrewsbury, MA (US)

(21) Appl. No.: 18/065,955

(22) Filed: Dec. 14, 2022

Related U.S. Application Data
(60) Provisional application No. 63/265,646, filed on Dec. 17, 2021.

(51) Int. Cl. B32B 27/20; C08K 3/36; C08K 3/22; B32B 7/02; B32B 5/02; B32B 7/12; B32B 27/32; B32B 27/12; B32B 27/08; H05K 1/02

(52) U.S. Cl. CPC B32B 27/20; C08K 3/36; C08K 3/22; B32B 7/02; B32B 5/022; B32B 5/024; B32B 7/12; B32B 27/322; B32B 27/12; B32B 27/08; H05K 1/0271; C08K 2003/2241; B32B 2262/101; B32B 2264/107; B32B 2264/303; B32B 2307/732; B32B 2307/54; B32B 2307/204; B32B 2457/08; H05K 1/0366

(57) ABSTRACT

The present disclosure relates to a dielectric composite may include a dielectric substrate overlying a reinforcement fabric layer. The dielectric substrate may include a resin matrix component, and a ceramic filler component. The ceramic filler component may include a first filler material. The particle size distribution of the first filler material may have a D₁₀ of at least about 1.0 microns and not greater than about 1.7, a D₅₀ of at least about 1.0 microns and not greater than about 3.5 microns, and a D₉₀ of at least about 2.7 microns and not greater than about 6 microns.

### CROSS-REFERENCE TO RELATED APPLICATION(S)

This application claims priority under 35 U.S.C. § 119(e) to U.S. Provisional Patent Application No. 63/265,646, entitled “DIELECTRIC SUBSTRATE AND METHOD OF FORMING THE SAME,” by Jennifer ADAMCHUK et al., filed Dec. 17, 2021, which is assigned to the current assignee hereof and is incorporated herein by reference in its entirety.

### FIELD OF THE DISCLOSURE

The present disclosure relates to a dielectric substrate and methods of forming the same. In particular, the present disclosure related to a dielectric substrate for use in a copper-clad laminate structure and a method of forming the same.

### BACKGROUND

Copper-clad laminates (CCLs) include a dielectric material laminated onto or between two layers of conductive copper foil. Subsequent operations transform such CCLs into printed circuit boards (PCBs). When used to form PCBs, the conductive copper foil is selectively etched to form circuitry with through holes that are drilled between layers and metalized, i.e., plated, to establish conductivity between layers in multilayer PCBs. CCLs must therefore exhibit excellence thermomechanical stability. PCBs are also routinely exposed to excessively high temperatures during manufacturing operations, such as soldering, as well as in service. Consequently, they must function at continuous temperatures above 200° C. without deforming and withstand dramatic temperature fluctuations while resisting moisture absorption. The dielectric layer of a CCL serves as a spacer between the conductive layers and can minimize electrical signal loss and crosstalk by blocking electrical conductivity. The lower the dielectric constant (permittivity) of the dielectric layer is, the higher the speed of the electrical signal through the layer will be. A low dissipation factor, which is dependent upon temperature and frequency, as well as the polarizability of the material, is therefore very critical for high-frequency applications. Accordingly, improved dielectric materials and dielectric layers that can be used in PCBs and other high-frequency applications are desired.

### SUMMARY

According to a first aspect, a dielectric composite may include a dielectric substrate overlying a reinforcement fabric layer. The dielectric substrate may include a resin matrix component, and a ceramic filler component. The ceramic filler component may include a first filler material. The particle size distribution of the first filler material may have a D₁₀ of at least about 0.5 microns and not greater than about 1.6, a D₅₀ of at least about 0.8 microns and not greater than about 2.7 microns, and a D₉₀ of at least about 1.5 microns and not greater than about 4.7 microns.

According to another aspect, a dielectric composite may include a dielectric substrate overlying a reinforcement fabric layer. The dielectric substrate may include a resin matrix component, and a ceramic filler component. The ceramic filler component may include a first filler material. The first filler material may further have a mean particle size of not greater than about 10 microns, and a particle size distribution span (PSDS) of not greater than about 5, where PSDS is equal to (D₉₀−D₁₀)/D₅₀, where D₉₀ is equal to a D₉₀ particle size distribution measurement of the first filler material, D₁₀ is equal to a D₁₀ particle size distribution measurement of the first filler material, and D₅₀ is equal to a D₅₀ particle size distribution measurement of the first filler material.

According to still another aspect, a dielectric composite may include a dielectric substrate overlying a reinforcement fabric layer. The dielectric substrate may include a resin matrix component, and a ceramic filler component. The ceramic filler component may include a first filler material. The first filler material may further have a mean particle size of not greater than about 10 microns, and an average surface area of not greater than about 8.0 m²/g.

According to another aspect, a copper-clad laminate may include a copper foil layer and a dielectric composite overlying the copper foil layer. The dielectric composite may include a dielectric substrate overlying a reinforcement fabric layer. The dielectric substrate may include a resin matrix component, and a ceramic filler component. The ceramic filler component may include a first filler material that may include silica. The particle size distribution of the first filler material may have a D₁₀ of at least about 0.5 microns and not greater than about 1.6, a D₅₀ of at least about 0.8 microns and not greater than about 2.7 microns, and a D₉₀ of at least about 1.5 microns and not greater than about 4.7 microns.

According to yet another aspect, a copper-clad laminate may include a copper foil layer and a dielectric composite overlying the copper foil layer. The dielectric composite may include a dielectric substrate overlying a reinforcement fabric layer. The dielectric substrate may include a resin matrix component, and a ceramic filler component. The ceramic filler component may include a first filler material. The first filler material may further have a mean particle size of not greater than about 10 microns, and a particle size distribution span (PSDS) of not greater than about 5, where PSDS is equal to (D₉₀−D₁₀)/D₅₀, where D₉₀ is equal to a D₉₀ particle size distribution measurement of the first filler material, D₁₀ is equal to a D₁₀ particle size distribution measurement of the first filler material, and D₅₀ is equal to a D₅₀ particle size distribution measurement of the first filler material.

According to still another aspect, a copper-clad laminate may include a copper foil layer and a dielectric composite overlying the copper foil layer. The dielectric composite may include a dielectric substrate overlying a reinforcement fabric layer. The dielectric substrate may include a resin matrix component, and a ceramic filler component. The ceramic filler component may include a first filler material. The first filler material may further have a mean particle size of not greater than about 10 microns, and an average surface area of not greater than about 8.0 m²/g.

According to another aspect, a method of forming a dielectric composite may include providing a reinforcement fabric layer; combining a resin matrix precursor component and a ceramic filler precursor component to form a forming mixture; and forming the forming mixture into a dielectric substrate. The ceramic filler precursor component may include a first filler precursor material. The particle size distribution of the first filler material may have a D₁₀ of at least about 0.5 microns and not greater than about 1.6, a D₅₀ of at least about 0.8 microns and not greater than about 2.7 microns, and a D₉₀ of at least about 1.5 microns and not greater than about 4.7 microns.

According to another aspect, a method of forming a dielectric composite may include providing a reinforcement fabric layer; combining a resin matrix precursor component and a ceramic filler precursor component to form a forming mixture; and forming the forming mixture into a dielectric substrate. The ceramic filler precursor component may include a first filler precursor material. The first filler precursor material may further have a mean particle size of not greater than about 10 microns, and a particle size distribution span (PSDS) of not greater than about 5, where PSDS is equal to (D₉₀−D₁₀)/D₅₀, where D₉₀ is equal to a D₉₀ particle size distribution measurement of the first filler precursor material, D₁₀ is equal to a D₁₀ particle size distribution measurement of the first filler precursor material, and D₅₀ is equal to a D₅₀ particle size distribution measurement of the first filler precursor material.

According to still another aspect, a method of forming a dielectric composite may include providing a reinforcement fabric layer; combining a resin matrix precursor component and a ceramic filler precursor component to form a forming mixture; and forming the forming mixture into a dielectric substrate. The ceramic filler precursor component may include a first filler precursor material. The first filler material may further have a mean particle size of not greater than about 10 microns, and an average surface area of not greater than about 8.0 m²/g.

According to another aspect, a method of forming a copper-clad laminate may include providing a copper foil layer, providing a reinforcement fabric layer overlying the copper foil layer, combining a resin matrix precursor component and a ceramic filler precursor component to form a forming mixture, and forming the forming mixture into a dielectric substrate overlying a reinforcement fabric layer. The ceramic filler precursor component may include a first filler precursor material. The particle size distribution of the first filler material may have a D₁₀ of at least about 0.5 microns and not greater than about 1.6, a D₅₀ of at least about 0.8 microns and not greater than about 2.7 microns, and a D₉₀ of at least about 1.5 microns and not greater than about 4.7 microns.

According to yet another aspect, a method of forming a copper-clad laminate may include providing a copper foil layer, providing a reinforcement fabric layer overlying the copper foil layer, combining a resin matrix precursor component and a ceramic filler precursor component to form a forming mixture, and forming the forming mixture into a dielectric substrate overlying the reinforcement fabric layer. The ceramic filler precursor component may include a first filler precursor material. The first filler precursor material may further have a mean particle size of not greater than about 10 microns, and a particle size distribution span (PSDS) of not greater than about 5, where PSDS is equal to (D₉₀−D₁₀)/D₅₀, where D₉₀ is equal to a D₉₀ particle size distribution measurement of the first filler precursor material, D₁₀ is equal to a D₁₀ particle size distribution measurement of the first filler precursor material, and D₅₀ is equal to a D₅₀ particle size distribution measurement of the first filler precursor material.

According to still another aspect, a method of forming a copper-clad laminate may include providing a copper foil layer, providing a reinforcement fabric layer overlying the copper foil layer, combining a resin matrix precursor component and a ceramic filler precursor component to form a forming mixture, and forming the forming mixture into a dielectric substrate overlying the reinforcement fabric layer. The ceramic filler precursor component may include a first filler precursor material. The first filler material may further have a mean particle size of not greater than about 10 microns, and an average surface area of not greater than about 8.0 m²/g.

### BRIEF DESCRIPTION OF THE DRAWINGS

Embodiments are illustrated by way of example and are not limited to the accompanying figures.

FIG. 1 includes a diagram showing a dielectric layer forming method according to embodiments described herein;

FIG. 2 includes an illustration showing the configuration of a dielectric layer formed according to embodiments described herein;

FIG. 3 includes a diagram showing a copper-clad laminate forming method according to embodiments described herein;

FIG. 4 includes an illustration showing the configuration of a copper-clad laminate formed according to embodiments described herein;

FIG. 5 includes a diagram showing a printed circuit board forming method according to embodiments described herein; and

FIG. 6 includes an illustration showing the configuration of a printed circuit board formed according to embodiments described herein.

Skilled artisans appreciate that elements in the figures are illustrated for simplicity and clarity and have not necessarily been drawn to scale.

### DETAILED DESCRIPTION

The following discussion will focus on specific implementations and embodiments of the teachings. The detailed description is provided to assist in describing certain embodiments and should not be interpreted as a limitation on the scope or applicability of the disclosure or teachings. It will be appreciated that other embodiments can be used based on the disclosure and teachings as provided herein.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present), and B is false (or not present), A is false (or not present), and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

Embodiments described herein are generally directed to a dielectric substrate that may include a resin matrix component, and a ceramic filler component.

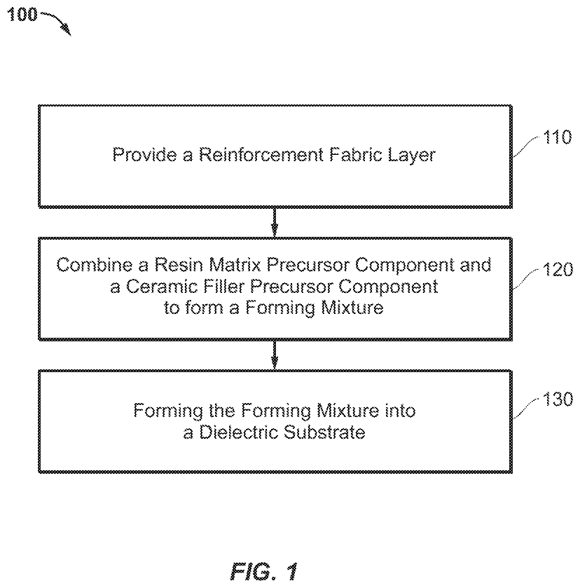

Referring first to a method of forming a dielectric substrate, FIG. 1 includes a diagram showing a forming method 100 for forming a dielectric composite according to embodiments described herein. According to particular embodiments, the forming method 100 may include a first step 110 of providing a reinforcement fabric layer, a second step 120 of combining a resin matrix precursor component and a ceramic filler precursor component to form a forming mixture, and a third step 130 of forming the forming mixture into a dielectric substrate.

According to particular embodiments, the ceramic filler precursor component may include a first filler precursor material, which may have particular characteristics that may improve performance of the dielectric composite formed by the forming method 100.

Referring first to the first step 110, according to particular embodiments, the reinforcement fabric layer may include a glass fabric material. According to still other embodiments, the reinforcement fabric layer may include E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof. According to still other embodiments, the reinforcement fabric layer may include a woven fabric or fibrous material. According to so yet other embodiments, the fibrous material may include E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof. According to yet other embodiments, the reinforcement fabric layer may include a non-woven fabric of fibrous material. According to so yet other embodiments, the fibrous material may include E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof.

According to still other embodiments, the reinforcement fabric layer may have a particular thickness. For example, the reinforcement fabric layer may have thickness of at least about 4 microns, such as, at least about 5 microns or at least 6 microns or at least about 7 microns or at least about 8 microns or at least about 9 microns or at least about 10 microns or at least about 11 microns or even at least about 12 microns. According to still other embodiments, the reinforcement fabric layer may have a thickness of not greater than about 1000 microns, such as, not greater than about 900 microns or not greater than about 800 microns or not greater than about 700 microns or not greater than about 600 microns or not greater than about 500 microns or not greater than about 400 microns or not greater than about 300 microns or even not greater than about 200 microns. It will be appreciated that the thickness of the reinforcement fabric layer may be any value between, and including, any of the minimum and maximum values noted above. It will be further appreciated that the thickness of the reinforcement fabric layer may be within a range between, and including, any of the minimum and maximum values noted above.

According to certain embodiments, the first filler precursor material may have a particular size distribution. For purposes of embodiments described herein, the particle size distribution of a material, for example, the particle size distribution of a first filler precursor material may be described using any combination of particle size distribution D-values D₁₀, D₅₀ and D₉₀. The D₁₀ value from a particle size distribution is defined as a particle size value where 10% of the particles are smaller than the value and 90% of the particles are larger than the value. The D₅₀ value from a particle size distribution is defined as a particle size value where 50% of the particles are smaller than the value and 50% of the particles are larger than the value. The D₉₀ value from a particle size distribution is defined as a particle size value where 90% of the particles are smaller than the value and 10% of the particles are larger than the value. For purposes of embodiments described herein, particle size measurements for a particular material are made using laser diffraction spectroscopy.

According to certain embodiments, the first filler precursor material may have a particular size distribution D₁₀ value. For example, the D₁₀ of the first filler precursor material may be at least about 0.5 microns, such as, at least about 0.6 microns or at least about 0.7 microns or at least about 0.8 microns or at least about 0.9 microns or at least about 1.0 microns or at least about 1.1 microns or even at least about 1.2 microns. According to still other embodiments, the D₁₀ of the first filler material may be not greater than about 1.6 microns, such as, not greater than about 1.5 microns or even not greater than about 1.4 microns. It will be appreciated that the D₁₀ of the first filler precursor material may be any value between, and including, any of the minimum and maximum values noted above. It will be further appreciated that the D₁₀ of the first filler precursor material may be within a range between, and including, any of the minimum and maximum values noted above.

According to other embodiments, the first filler precursor material may have a particular size distribution D₅₀ value. For example, the D₅₀ of the first filler precursor material may be at least about 0.8 microns, such as, at least about 0.9 microns or at least about 1.0 microns or at least about 1.1 microns or at least about 1.2 microns or at least about 1.3 microns or at least about 1.4 microns or at least about 1.5 microns or at least about 1.6 microns or at least about 1.7 microns or at least about 1.8 microns or at least about 1.9 microns or at least about 2.0 microns or at least about 2.1 microns or even at least about 2.2 microns. According to still other embodiments, the D₅₀ of the first filler material may be not greater than about 2.7 microns, such as, not greater than about 2.6 microns or not greater than about 2.5 microns or even not greater than about 2.4. It will be appreciated that the D₅₀ of the first filler precursor material may be any value between, and including, any of the minimum and maximum values noted above. It will be further appreciated that the D₅₀ of the first filler precursor material may be within a range between, and including, any of the minimum and maximum values noted above.

According to other embodiments, the first filler precursor material may have a particular size distribution D₉₀ value. For example, the D₉₀ of the first filler precursor material may be at least about 1.5 microns, such as, at least about 1.6 microns or at least about 1.7 microns or at least about 1.8 microns or at least about 1.9 microns or at least about 2.0 microns or at least about 2.1 microns or at least about 2.2 microns or at least about 2.3 microns or at least about 2.4 microns or at least about 2.5 microns or at least about 2.6 microns or even at least about 2.7 microns. According to still other embodiments, the D₉₀ of the first filler material may be not greater than about 8.0 microns, such as, not greater than about 7.5 microns or not greater than about 7.0 microns or not greater than about 6.5 microns or not greater than about 6.0 microns or not greater than about 5.5 microns or not greater than about 5.4 microns or not greater than about 5.3 microns or not greater than about 5.2 or even not greater than about 5.1 microns. It will be appreciated that the D₉₀ of the first filler precursor material may be any value between, and including, any of the minimum and maximum values noted above. It will be further appreciated that the D₉₀ of the first filler precursor material may be within a range between, and including, any of the minimum and maximum values noted above.

According to still other embodiments, the first filler precursor material may have a particular mean particle size as measured using laser diffraction spectroscopy. For example, the mean particle size of the first filler precursor material may be not greater than about 10 microns, such as, not greater than about 9 microns or not greater than about 8 microns or not greater than about 7 microns or not greater than about 6 microns or not greater than about 5 microns or not greater than about 4 microns or not greater than about 3 microns or even not greater than about 2 microns. It will be appreciated that the mean particle size of the first filler precursor material may be any value between, and including, any of the values noted above. It will be further appreciated that the mean particle size of the first filler precursor material may be within a range between, and including, any of the values noted above.

According to still other embodiments, the first filler precursor material may be described as having a particular particle size distribution span (PSDS), where the PSDS is equal to (D₉₀−D₁₀)/D₅₀, where D₉₀ is equal to a D₉₀ particle size distribution measurement of the first filler precursor material, D₁₀ is equal to a D₁₀ particle size distribution measurement of the first filler precursor material, and D₅₀ is equal to a D₅₀ particle size distribution measurement of the first filler precursor material. For example, the PSDS of the first filler precursor material may be not greater than about 5, such as, not greater than about 4.5 or not greater than about 4.0 or not greater than about 3.5 or not greater than about 3.0 or even not greater than about 2.5. It will be appreciated that the PSDS of the first filler precursor material may be any value between, and including, any of the values noted above. It will be further appreciated that the PSDS of the first filler precursor material may be within a range between, and including, any of the values noted above.

According to still other embodiments, the first filler precursor material may be described as having a particular average surface area as measured using Brunauer-Emmett-Teller (BET) surface area analysis (Nitrogen Adsorption). For example, the first filler precursor material may have an average surface area of not greater than about 8 m²/g, such as, not greater than about 7.9 m²/g or not greater than about 7.5 m²/g or not greater than about 7.0 m²/g or not greater than about 6.5 m²/g or not greater than about 6.0 m²/g or not greater than about 5.5 m²/g or not greater than about 5.0 m²/g or not greater than about 4.5 m²/g or not greater than about 4.0 m²/g or even not greater than about 3.5 m²/g. According to still other embodiments, the first filler precursor material may have an average surface area of at least about 1.2 m²/g, such as, at least about 2.2 m²/g. It will be appreciated that the average surface area of the first filler precursor material may be any value between, and including, any of the minimum and maximum values noted above. It will be further appreciated that the average surface area of the first filler precursor material may be within a range between, and including, any of the minimum and maximum values noted above.

According to other embodiments, the first filler precursor material may include a particular material. According to particular embodiments, the first filler precursor material may include a silica-based compound. According to still other embodiments, the first filler precursor material may consist of a silica-based compound. According to other embodiments, the first filler precursor material may include silica. According to still other embodiments, the first filler precursor material may consist of silica.

According to yet other embodiments, the forming mixture may include a particular content of the ceramic filler precursor component. For example, the content of the ceramic filler precursor component may be at least about 45 vol. % for a total volume of the forming mixture, such as, at least about 46 vol. % or at least about 47 vol. % or at least about 48 vol. % or at least about 49 vol. % or at least about 50 vol. % or at least about 51 vol. % or at least about 52 vol. % or at least about 53 vol. % or even at least about 54 vol. %. According to still other embodiments, the content of the ceramic filler precursor component may be not greater than about 57 vol. % for a total volume of the forming mixture, such as, not greater than about 56 vol. % or even not greater than about 55 vol. %. It will be appreciated that the content of the ceramic filler precursor component may be any value between, and including, any of the minimum and maximum values noted above. It will be further appreciated that the content of the ceramic filler precursor component may be within a range between, and including, any of the minimum and maximum values noted above.

According to still other embodiments, the ceramic filler precursor component may include a particular content of the first filler precursor material. For example, the content of the first filler precursor material may be at least about 80 vol. % for a total volume of the ceramic filler precursor component, such as, at least about 81 vol. % or at least about 82 vol. % or at least about 83 vol. % or at least about 84 vol. % or at least about 85 vol. % or at least about 86 vol. % or at least about 87 vol. % or at least about 88 vol. % or at least about 89 vol. % or even at least about 90 vol. %. According to still other embodiments, the content of the first filler precursor material may be not greater than about 100 vol. % for a total volume of the ceramic filler precursor component, such as, not greater than about 99 vol. % or not greater than about 98 vol. % or not greater than about 97 vol. % or not greater than about 96 vol. % or not greater than about 95 vol. % or not greater than about 94 vol. % or not greater than about 93 vol. % or even not greater than about 92 vol. %. It will be appreciated that the content of the first filler precursor material may be any value between, and including, any of the minimum and maximum values noted above. It will be further appreciated that the content of the first filler precursor material may be within a range between, and including, any of the minimum and maximum values noted above.

According to still other embodiments, the ceramic filler precursor component may include a second filler precursor material.

According to yet other embodiments, the second filler precursor material may include a particular material. For example, the second filler precursor material may include a high dielectric constant ceramic material, such as, a ceramic material having a dielectric constant of at least about 14. According to particular embodiments, the second filler precursor material may include any high dielectric constant ceramic material, such as, TiO₂, SrTiO₃, ZrTi₂O₆, MgTiO₃, CaTiO₃, BaTiO₄ or any combination thereof.

According to yet other embodiments, the second filler precursor material may include TiO₂. According to still other embodiments, the second filler precursor material may consist of TiO₂.

According to still other embodiments, the ceramic filler precursor component may include a particular content of the second filler precursor material. For example, the content of the second filler precursor material may be at least about 1 vol. % for a total volume of the ceramic filler precursor component, such as, at least about 2 vol. % or at least about 3 vol. % or at least about 4 vol. % or at least about 5 vol. % or at least about 6 vol. % or at least about 7 vol. % or at least about 8 vol. % or at least about 9 vol. % or at least about 10 vol. %. According to still other embodiments, the content of the second filler precursor material may be not greater than about 20 vol. % for a total volume of the ceramic filler precursor component, such as, not greater than about 19 vol. % or not greater than about 18 vol. % or not greater than about 17 vol. % or not greater than about 16 vol. % or not greater than about 15 vol. % or not greater than about 14 vol. % or not greater than about 13 vol. % or not greater than about 12 vol. %. It will be appreciated that the content of the second filler precursor material may be any value between, and including, any of the minimum and maximum values noted above. It will be further appreciated that the content of the second filler precursor material may be within a range between, and including, any of the minimum and maximum values noted above.

According to yet other embodiments, the ceramic filler precursor component may include a particular content of amorphous material. For example, the ceramic filler precursor component may include at least about 97% amorphous material, such as, at least about 98% or even at least about 99%. It will be appreciated that the content of amorphous material may be any value between, and including, any of the values noted above. It will be further appreciated that the content of the content of amorphous material may be within a range between, and including, any of the values noted above. According to other embodiments, the resin matrix precursor component may include a particular material. For example, the resin matrix precursor component may include a perfluoropolymer. According to still other embodiments, the resin matrix precursor component may consist of a perfluoropolymer.

According to yet other embodiments, the perfluoropolymer of the resin matrix precursor component may include a copolymer of tetrafluoroethylene (TFE); a copolymer of hexafluoropropylene (HFP); a terpolymer of tetrafluoroethylene (TFE); or any combination thereof. According to other embodiments, the perfluoropolymer of the resin matrix precursor component may consist of a copolymer of tetrafluoroethylene (TFE); a copolymer of hexafluoropropylene (HFP); a terpolymer of tetrafluoroethylene (TFE); or any combination thereof.

According to yet other embodiments, the perfluoropolymer of the resin matrix precursor component may include polytetrafluoroethylene (PTFE), perfluoroalkoxy polymer resin (PFA), fluorinated ethylene propylene (FEP), or any combination thereof. According to still other embodiments, the perfluoropolymer of the resin matrix precursor component may consist of polytetrafluoroethylene (PTFE), perfluoroalkoxy polymer resin (PFA), fluorinated ethylene propylene (FEP), or any combination thereof.

According to yet other embodiments, the forming mixture may include a particular content of the resin matrix precursor component. For example, the content of the resin matrix precursor component may be at least about 45 vol. % for a total volume of the forming mixture, such as, at least about 46 vol. % or at least about 47 vol. % or at least about 48 vol. % or at least about 49 vol. % or at least about 50 vol. % or at least about 51 vol. % or at least about 52 vol. % or at least about 53 vol. % or at least about 54 vol. % or even at least about 55 vol. %. According to still other embodiments, the content of the resin matrix precursor component is not greater than about 63 vol. % for a total volume of the forming mixture or not greater than about 62 vol. % or not greater than about 61 vol. % or not greater than about 60 vol. % or not greater than about 59 vol. % or not greater than about 58 vol. % or even not greater than about 57 vol. %. It will be appreciated that the content of the resin matrix precursor component may be any value between, and including, any of the minimum and maximum values noted above. It will be further appreciated that the content of the resin matrix precursor component may be within a range between, and including, any of the minimum and maximum values noted above.

According to yet other embodiments, the forming mixture may include a particular content of the perfluoropolymer. For example, the content of the perfluoropolymer may be at least about 45 vol. % for a total volume of the forming mixture, such as, at least about 46 vol. % or at least about 47 vol. % or at least about 48 vol. % or at least about 49 vol. % or at least about 50 vol. % or at least about 51 vol. % or at least about 52 vol. % or at least about 53 vol. % or at least about 54 vol. % or even at least about 55 vol. %. According to still other embodiments, the content of the perfluoropolymer may be not greater than about 63 vol. % for a total volume of the forming mixture, such as, not greater than about 62 vol. % or not greater than about 61 vol. % or not greater than about 60 vol. % or not greater than about 59 vol. % or not greater than about 58 vol. % or even not greater than about 57 vol. %. It will be appreciated that the content of the perfluoropolymer may be any value between, and including, any of the minimum and maximum values noted above. It will be further appreciated that the content of the perfluoropolymer may be within a range between, and including, any of the minimum and maximum values noted above.

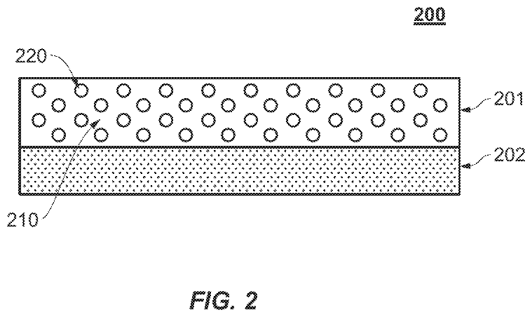

Referring now to embodiments of the dielectric substrate formed according to forming method 100, FIG. 2 includes diagram of a dielectric composite 200. As shown in FIG. 2, the dielectric composite 200 may include a dielectric substrate 201 overlying a reinforcement fabric layer 202. As further shown in FIG. 2, the dielectric substrate 201 may include a resin matrix component 210 and a ceramic filler component 220.

According to particular embodiments, the reinforcement fabric layer 202 may include a glass fabric material. According to still other embodiments, the reinforcement fabric layer 202 may include E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof. According to still other embodiments, the reinforcement fabric layer 202 may include a woven fabric or fibrous material. According to so yet other embodiments, the fibrous material may include E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof. According to yet other embodiments, the reinforcement fabric layer 202 may include a non-woven fabric of fibrous material. According to so yet other embodiments, the fibrous material may include E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof.

According to still other embodiments, the reinforcement fabric layer 202 may have a particular thickness. For example, the reinforcement fabric layer 202 may have thickness of at least about 4 microns, such as, at least about 5 microns or at least 6 microns or at least about 7 microns or at least about 8 microns or at least about 9 microns or at least about 10 microns or at least about 11 microns or even at least about 12 microns. According to still other embodiments, the reinforcement fabric layer 202 may have a thickness of not greater than about 1000 microns, such as, not greater than about 900 microns or not greater than about 800 microns or not greater than about 700 microns or not greater than about 600 microns or not greater than about 500 microns or not greater than about 400 microns or not greater than about 300 microns or even not greater than about 200 microns. It will be appreciated that the thickness of the reinforcement fabric layer 202 may be any value between, and including, any of the minimum and maximum values noted above. It will be further appreciated that the thickness of the reinforcement fabric layer 202 may be within a range between, and including, any of the minimum and maximum values noted above.

According to particular embodiments, the ceramic filler component 220 may include a first filler material, which may have particular characteristics that may improve performance of the dielectric substrate 201.

According to certain embodiments, the first filler material of the ceramic filler component 220 may have a particular size distribution. For purposes of embodiments described herein, the particle size distribution of a material, for example, the particle size distribution of a first filler material may be described using any combination of particle size distribution D-values D₁₀, D₅₀ and D₉₀. The D₁₀ value from a particle size distribution is defined as a particle size value where 10% of the particles are smaller than the value and 90% of the particles are larger than the value. The D₅₀ value from a particle size distribution is defined as a particle size value where 50% of the particles are smaller than the value and 50% of the particles are larger than the value. The D₉₀ value from a particle size distribution is defined as a particle size value where 90% of the particles are smaller than the value and 10% of the particles are larger than the value. For purposes of embodiments described herein, particle size measurements for a particular material are made using laser diffraction spectroscopy.

According to certain embodiments, the first filler material of the ceramic filler component 220 may have a particular size distribution D₁₀ value. For example, the D₁₀ of the first filler material may be at least about 0.5 microns, such as, at least about 0.6 microns or at least about 0.7 microns or at least about 0.8 microns or at least about 0.9 microns or at least about 1.0 microns or at least about 1.1 microns or even at least about 1.2 microns. According to still other embodiments, the D₁₀ of the first filler material may be not greater than about 1.6 microns, such as, not greater than about 1.5 microns or even not greater than about 1.4 microns. It will be appreciated that the D₁₀ of the first filler material may be any value between, and including, any of the minimum and maximum values noted above. It will be further appreciated that the D₁₀ of the first filler material may be within a range between, and including, any of the minimum and maximum values noted above.

According to other embodiments, the first filler material of the ceramic filler component 220 may have a particular size distribution D₅₀ value. For example, the D₅₀ of the first filler material may be at least about 0.8 microns, such as, at least about 0.9 microns or at least about 1.0 microns or at least about 1.1 microns or at least about 1.2 microns or at least about 1.3 microns or at least about 1.4 microns or at least about 1.5 microns or at least about 1.6 microns or at least about 1.7 microns or at least about 1.8 microns or at least about 1.9 microns or at least about 2.0 microns or at least about 2.1 microns or even at least about 2.2 microns. According to still other embodiments, the D₅₀ of the first filler material may be not greater than about 2.7 microns, such as, not greater than about 2.6 microns or not greater than about 2.5 microns or even not greater than about 2.4. It will be appreciated that the D₅₀ of the first filler material may be any value between, and including, any of the minimum and maximum values noted above. It will be further appreciated that the D₅₀ of the first filler material may be within a range between, and including, any of the minimum and maximum values noted above.

According to other embodiments, the first filler material of the ceramic filler component 220 may have a particular size distribution D₉₀ value. For example, the D₉₀ of the first filler material may be at least about 1.5 microns, such as, at least about 1.6 microns or at least about 1.7 microns or at least about 1.8 microns or at least about 1.9 microns or at least about 2.0 microns or at least about 2.1 microns or at least about 2.2 microns or at least about 2.3 microns or at least about 2.4 microns or at least about 2.5 microns or at least about 2.6 microns or even at least about 2.7 microns. According to still other embodiments, the D₉₀ of the first filler material may be not greater than about 8.0 microns, such as, not greater than about 7.5 microns or not greater than about 7.0 microns or not greater than about 6.5 microns or not greater than about 6.0 microns or not greater than about 5.5 microns or not greater than about 5.4 microns or not greater than about 5.3 microns or not greater than about 5.2 or even not greater than about 5.1 microns. It will be appreciated that the D₉₀ of the first filler material may be any value between, and including, any of the minimum and maximum values noted above. It will be further appreciated that the D₉₀ of the first filler material may be within a range between, and including, any of the minimum and maximum values noted above.

According to still other embodiments, the first filler material of the ceramic filler component 220 may have a particular mean particle size as measured according to laser diffraction spectroscopy. For example, the mean particle size of the first filler material may be not greater than about 10 microns, such as, not greater than about 9 microns or not greater than about 8 microns or not greater than about 7 microns or not greater than about 6 microns or not greater than about 5 microns or not greater than about 4 microns or not greater than about 3 microns or even not greater than about 2 microns. It will be appreciated that the mean particle size of the first filler material may be any value between, and including, any of the values noted above. It will be further appreciated that the mean particle size of the first filler material may be within a range between, and including, any of the values noted above.

According to still other embodiments, the first filler material of the ceramic filler component 220 may be described as having a particular particle size distribution span (PSDS), where the PSDS is equal to (D₉₀−D₁₀)/D₅₀, where D₉₀ is equal to a D₉₀ particle size distribution measurement of the first filler material, D₁₀ is equal to a D₁₀ particle size distribution measurement of the first filler material, and D₅₀ is equal to a D₅₀ particle size distribution measurement of the first filler material. For example, the PSDS of the first filler material may be not greater than about 5, such as, not greater than about 4.5 or not greater than about 4.0 or not greater than about 3.5 or not greater than about 3.0 or even not greater than about 2.5. It will be appreciated that the PSDS of the first filler material may be any value between, and including, any of the values noted above. It will be further appreciated that the PSDS of the first filler material may be within a range between, and including, any of the values noted above.

According to still other embodiments, the first filler material of the ceramic filler component 220 may be described as having a particular average surface area as measured using Brunauer-Emmett-Teller (BET) surface area analysis (Nitrogen Adsorption). For example, the first filler material may have an average surface area of not greater than about 8 m²/g, such as, not greater than about 7.9 m²/g or not greater than about 7.5 m²/g or not greater than about 7.0 m²/g or not greater than about 6.5 m²/g or not greater than about 6.0 m²/g or not greater than about 5.5 m²/g or not greater than about 5.0 m²/g or not greater than about 4.5 m²/g or not greater than about 4.0 m²/g or even not greater than about 3.5 m²/g. According to still other embodiments, the first filler material may have an average surface area of at least about 1.2 m²/g, such as, at least about 2.2 m²/g. It will be appreciated that the average surface area of the first filler material may be any value between, and including, any of the minimum and maximum values noted above. It will be further appreciated that the average surface area of the first filler material may be within a range between, and including, any of the minimum and maximum values noted above.

According to other embodiments, the first filler material of the ceramic filler component 220 may include a particular material. According to particular embodiments, the first filler material may include a silica-based compound. According to still other embodiments, the first filler material may consist of a silica-based compound. According to other embodiments, the first filler material may include silica. According to still other embodiments, the first filler material may consist of silica.

According to yet other embodiments, the dielectric substrate 201 may include a particular content of the ceramic filler component 220. For example, the content of the ceramic filler component 220 may be at least about 45 vol. % for a total volume of the dielectric substrate 201, such as, at least about 46 vol. % or at least about 47 vol. % or at least about 48 vol. % or at least about 49 vol. % or at least about 50 vol. % or at least about 51 vol. % or at least about 52 vol. % or at least about 53 vol. % or even at least about 54 vol. %. According to still other embodiments, the content of the ceramic filler component 220 may be not greater than about 57 vol. % for a total volume of the dielectric substrate 201, such as, not greater than about 56 vol. % or even not greater than about 55 vol. %. It will be appreciated that the content of the ceramic filler component 220 may be any value between, and including, any of the minimum and maximum values noted above. It will be further appreciated that the content of the ceramic filler component 220 may be within a range between, and including, any of the minimum and maximum values noted above.

According to still other embodiments, the ceramic filler component 220 may include a particular content of the first filler material. For example, the content of the first filler material may be at least about 80 vol. % for a total volume of the ceramic filler component 220, such as, at least about 81 vol. % or at least about 82 vol. % or at least about 83 vol. % or at least about 84 vol. % or at least about 85 vol. % or at least about 86 vol. % or at least about 87 vol. % or at least about 88 vol. % or at least about 89 vol. % or even at least about 90 vol. %. According to still other embodiments, the content of the first filler material may be not greater than about 100 vol. % for a total volume of the ceramic filler component 220, such as, not greater than about 99 vol. % or not greater than about 98 vol. % or not greater than about 97 vol. % or not greater than about 96 vol. % or not greater than about 95 vol. % or not greater than about 94 vol. % or not greater than about 93 vol. % or even not greater than about 92 vol. %. It will be appreciated that the content of the first filler material may be any value between, and including, any of the minimum and maximum values noted above. It will be further appreciated that the content of the first filler material may be within a range between, and including, any of the minimum and maximum values noted above.

According to still other embodiments, the ceramic filler component 220 may include a second filler material.

According to yet other embodiments, the second filler material of the ceramic filler component 220 may include a particular material. For example, the second filler material may include a high dielectric constant ceramic material, such as, a ceramic material having a dielectric constant of at least about 14. According to particular embodiments, the second filler material of the ceramic filler component 220 may include any high dielectric constant ceramic material, such as, TiO₂, SrTiO₃, ZrTi₂O₆, MgTiO₃, CaTiO₃, BaTiO₄ or any combination thereof.

According to yet other embodiments, the second filler material of the ceramic filler component 220 may include TiO₂. According to still other embodiments, the second filler material may consist of TiO₂.

According to still other embodiments, the ceramic filler component 220 may include a particular content of the second filler material. For example, the content of the second filler material may be at least about 1 vol. % for a total volume of the ceramic filler component 220, such as, at least about 2 vol. % or at least about 3 vol. % or at least about 4 vol. % or at least about 5 vol. % or at least about 6 vol. % or at least about 7 vol. % or at least about 8 vol. % or at least about 9 vol. % or at least about 10 vol. %. According to still other embodiments, the content of the second filler material may be not greater than about 20 vol. % for a total volume of the ceramic filler component 220, such as, not greater than about 19 vol. % or not greater than about 18 vol. % or not greater than about 17 vol. % or not greater than about 16 vol. % or not greater than about 15 vol. % or not greater than about 14 vol. % or not greater than about 13 vol. % or not greater than about 12 vol. %. It will be appreciated that the content of the second filler material may be any value between, and including, any of the minimum and maximum values noted above. It will be further appreciated that the content of the second filler material may be within a range between, and including, any of the minimum and maximum values noted above.

According to yet other embodiments, the ceramic filler component 220 may include a particular content of amorphous material. For example, the ceramic filler component 220 may include at least about 97% amorphous material, such as, at least about 98% or even at least about 99%. It will be appreciated that the content of amorphous material may be any value between, and including, any of the values noted above. It will be further appreciated that the content of the content of amorphous material may be within a range between, and including, any of the values noted above.

According to other embodiments, the resin matrix component 210 may include a particular material. For example, the resin matrix component 210 may include a perfluoropolymer. According to still other embodiments, the resin matrix component 210 may consist of a perfluoropolymer.

According to yet other embodiments, the perfluoropolymer of the resin matrix component 210 may include a copolymer of tetrafluoroethylene (TFE); a copolymer of hexafluoropropylene (HFP); a terpolymer of tetrafluoroethylene (TFE); or any combination thereof. According to other embodiments, the perfluoropolymer of the resin matrix component 210 may consist of a copolymer of tetrafluoroethylene (TFE); a copolymer of hexafluoropropylene (HFP); a terpolymer of tetrafluoroethylene (TFE); or any combination thereof.

According to yet other embodiments, the perfluoropolymer of the resin matrix component 210 may include polytetrafluoroethylene (PTFE), perfluoroalkoxy polymer resin (PFA), fluorinated ethylene propylene (FEP), or any combination thereof. According to still other embodiments, the perfluoropolymer of the resin matrix component 210 may consist of polytetrafluoroethylene (PTFE), perfluoroalkoxy polymer resin (PFA), fluorinated ethylene propylene (FEP), or any combination thereof.

According to yet other embodiments, the dielectric substrate 201 may include a particular content of the resin matrix component 210. For example, the content of the resin matrix component 210 may be at least about 45 vol. % for a total volume of the dielectric substrate 201, such as, at least about 46 vol. % or at least about 47 vol. % or at least about 48 vol. % or at least about 49 vol. % or at least about 50 vol. % or at least about 51 vol. % or at least about 52 vol. % or at least about 53 vol. % or at least about 54 vol. % or even at least about 55 vol. %. According to still other embodiments, the content of the resin matrix component 210 is not greater than about 63 vol. % for a total volume of the dielectric substrate 201 or not greater than about 62 vol. % or not greater than about 61 vol. % or not greater than about 60 vol. % or not greater than about 59 vol. % or not greater than about 58 vol. % or even not greater than about 57 vol. %. It will be appreciated that the content of the resin matrix component 210 may be any value between, and including, any of the minimum and maximum values noted above. It will be further appreciated that the content of the resin matrix component 210 may be within a range between, and including, any of the minimum and maximum values noted above.

According to yet other embodiments, the dielectric substrate 201 may include a particular content of the perfluoropolymer. For example, the content of the perfluoropolymer may be at least about 45 vol. % for a total volume of the dielectric substrate 201, such as, at least about 46 vol. % or at least about 47 vol. % or at least about 48 vol. % or at least about 49 vol. % or at least about 50 vol. % or at least about 51 vol. % or at least about 52 vol. % or at least about 53 vol. % or at least about 54 vol. % or even at least about 55 vol. %. According to still other embodiments, the content of the perfluoropolymer may be not greater than about 63 vol. % for a total volume of the dielectric substrate 201, such as, not greater than about 62 vol. % or not greater than about 61 vol. % or not greater than about 60 vol. % or not greater than about 59 vol. % or not greater than about 58 vol. % or even not greater than about 57 vol. %. It will be appreciated that the content of the perfluoropolymer may be any value between, and including, any of the minimum and maximum values noted above. It will be further appreciated that the content of the perfluoropolymer may be within a range between, and including, any of the minimum and maximum values noted above.

According to still other embodiments, the dielectric substrate 201 may include a particular porosity as measured using x-ray diffraction. For example, the porosity of the substrate 201 may be not greater than about 10 vol. %, such as, not greater than about 9 vol. % or not greater than about 8 vol. % or not greater than about 7 vol. % or not greater than about 6 vol. % or even not greater than about 5 vol. %. It will be appreciated that the porosity of the dielectric substrate 201 may be any value between, and including, any of the values noted above. It will be further appreciated that the porosity of the dielectric substrate 201 may be within a range between, and including, any of the values noted above.

According to yet other embodiments, the dielectric substrate 201 may have a particular average thickness. For example, the average thickness of the dielectric substrate 201 may be at least about 10 microns, such as, at least about 15 microns or at least about 20 microns or at least about 25 microns or at least about 30 microns or at least about 35 microns or at least about 40 microns or at least about 45 microns or at least about 50 microns or at least about 55 microns or at least about 60 microns or at least about 65 microns or at least about 70 microns or even at least about 75 microns. According to yet other embodiments, the average thickness of the dielectric substrate 201 may be not greater than about 2000 microns, such as, not greater than about 1800 microns or not greater than about 1600 microns or not greater than about 1400 microns or not greater than about 1200 microns or not greater than about 1000 microns or not greater than about 800 microns or not greater than about 600 microns or not greater than about 400 microns or not greater than about 200 microns or not greater than about 190 microns or not greater than about 180 microns or not greater than about 170 microns or not greater than about 160 microns or not greater than about 150 microns or not greater than about 140 microns or not greater than about 120 microns or even not greater than about 100 microns. It will be appreciated that the average thickness of the dielectric substrate 201 may be any value between, and including, any of the minimum and maximum values noted above. It will be further appreciated that the average thickness of the dielectric substrate 201 may be within a range between, and including, any of the minimum and maximum values noted above.

According to yet other embodiments, the dielectric substrate 201 may have a particular dissipation factor (Df) as measured in the range between 5 GHz, 20% RH. For example, the dielectric substrate 201 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 201 may be any value between, and including, any of the values noted above. It will be further appreciated that the dissipation factor of the dielectric substrate 201 may be within a range between, and including, any of the values noted above.

According to yet other embodiments, the dielectric substrate 201 may have a particular dissipation factor (Df) as measured in the range between 5 GHz, 80% RH. For example, the dielectric substrate 201 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 201 may be any value between, and including, any of the values noted above. It will be further appreciated that the dissipation factor of the dielectric substrate 201 may be within a range between, and including, any of the values noted above.

According to yet other embodiments, the dielectric substrate 201 may have a particular dissipation factor (Df) as measured in the range between 10 GHz, 20% RH. For example, the dielectric substrate 201 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 201 may be any value between, and including, any of the values noted above. It will be further appreciated that the dissipation factor of the dielectric substrate 201 may be within a range between, and including, any of the values noted above.

According to yet other embodiments, the dielectric substrate 201 may have a particular dissipation factor (Df) as measured in the range between 10 GHz, 80% RH. For example, the dielectric substrate 201 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 201 may be any value between, and including, any of the values noted above. It will be further appreciated that the dissipation factor of the dielectric substrate 201 may be within a range between, and including, any of the values noted above.

According to yet other embodiments, the dielectric substrate 201 may have a particular dissipation factor (Df) as measured in the range between 28 GHz, 20% RH. For example, the dielectric substrate 201 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 201 may be any value between, and including, any of the values noted above. It will be further appreciated that the dissipation factor of the dielectric substrate 201 may be within a range between, and including, any of the values noted above.

According to yet other embodiments, the dielectric substrate 201 may have a particular dissipation factor (Df) as measured in the range between 28 GHz, 80% RH. For example, the dielectric substrate 201 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 201 may be any value between, and including, any of the values noted above. It will be further appreciated that the dissipation factor of the dielectric substrate 201 may be within a range between, and including, any of the values noted above.

According to yet other embodiments, the dielectric substrate 201 may have a particular dissipation factor (Df) as measured in the range between 39 GHz, 20% RH. For example, the dielectric substrate 201 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 201 may be any value between, and including, any of the values noted above. It will be further appreciated that the dissipation factor of the dielectric substrate 201 may be within a range between, and including, any of the values noted above.

According to yet other embodiments, the dielectric substrate 201 may have a particular dissipation factor (Df) as measured in the range between 39 GHz, 80% RH. For example, the dielectric substrate 201 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 201 may be any value between, and including, any of the values noted above. It will be further appreciated that the dissipation factor of the dielectric substrate 201 may be within a range between, and including, any of the values noted above.

According to yet other embodiments, the dielectric substrate 201 may have a particular dissipation factor (Df) as measured in the range between 76-81 GHz, 20% RH. For example, the dielectric substrate 201 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 201 may be any value between, and including, any of the values noted above. It will be further appreciated that the dissipation factor of the dielectric substrate 201 may be within a range between, and including, any of the values noted above.

According to yet other embodiments, the dielectric substrate 201 may have a particular dissipation factor (Df) as measured in the range between 76-81 GHz, 80% RH. For example, the dielectric substrate 201 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 201 may be any value between, and including, any of the values noted above. It will be further appreciated that the dissipation factor of the dielectric substrate 201 may be within a range between, and including, any of the values noted above.

According to yet other embodiments, the dielectric substrate 201 may have a particular coefficient of thermal expansion as measured according to IPC-TM-650 2.4.24 Rev. C Glass Transition Temperature and Z-Axis Thermal Expansion by TMA. For example, the dielectric substrate 201 may have a coefficient of thermal expansion of not greater than about 80 ppm/° C.

According to yet other embodiments, the dielectric substrate 201 may have a particular coefficient of thermal expansion as measured according to IPC-TM-650 2.4.24 Rev. C Glass Transition Temperature and X-Axis Thermal Expansion by TMA. For example, the dielectric substrate 201 may have a coefficient of thermal expansion of not greater than about 80 ppm/° C.

According to yet other embodiments, the dielectric substrate 201 may have a particular coefficient of thermal expansion as measured according to IPC-TM-650 2.4.24 Rev. C Glass Transition Temperature and Y-Axis Thermal Expansion by TMA. For example, the dielectric substrate 201 may have a coefficient of thermal expansion of not greater than about 80 ppm/° C.

According to yet other embodiments, the dielectric composite 200 may have a particular dissipation factor (Df) as measured in the range between 5 GHz, 20% RH. For example, the dielectric composite 200 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 200 may be any value between, and including, any of the values noted above. It will be further appreciated that the dissipation factor of the dielectric composite 200 may be within a range between, and including, any of the values noted above.

According to yet other embodiments, the dielectric composite 200 may have a particular dissipation factor (Df) as measured in the range between 5 GHz, 80% RH. For example, the dielectric composite 200 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 200 may be any value between, and including, any of the values noted above. It will be further appreciated that the dissipation factor of the dielectric composite 200 may be within a range between, and including, any of the values noted above.

According to yet other embodiments, the dielectric composite 200 may have a particular dissipation factor (Df) as measured in the range between 10 GHz, 20% RH. For example, the dielectric composite 200 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 200 may be any value between, and including, any of the values noted above. It will be further appreciated that the dissipation factor of the dielectric composite 200 may be within a range between, and including, any of the values noted above.

According to yet other embodiments, the dielectric composite 200 may have a particular dissipation factor (Df) as measured in the range between 10 GHz, 80% RH. For example, the dielectric composite 200 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 200 may be any value between, and including, any of the values noted above. It will be further appreciated that the dissipation factor of the dielectric composite 200 may be within a range between, and including, any of the values noted above.

According to yet other embodiments, the dielectric composite 200 may have a particular dissipation factor (Df) as measured in the range between 28 GHz, 20% RH. For example, the dielectric composite 200 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 200 may be any value between, and including, any of the values noted above. It will be further appreciated that the dissipation factor of the dielectric composite 200 may be within a range between, and including, any of the values noted above.

According to yet other embodiments, the dielectric composite 200 may have a particular dissipation factor (Df) as measured in the range between 28 GHz, 80% RH. For example, the dielectric composite 200 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 200 may be any value between, and including, any of the values noted above. It will be further appreciated that the dissipation factor of the dielectric composite 200 may be within a range between, and including, any of the values noted above.

According to yet other embodiments, the dielectric composite 200 may have a particular dissipation factor (Df) as measured in the range between 39 GHz, 20% RH. For example, the dielectric composite 200 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 200 may be any value between, and including, any of the values noted above. It will be further appreciated that the dissipation factor of the dielectric composite 200 may be within a range between, and including, any of the values noted above.

According to yet other embodiments, the dielectric composite 200 may have a particular dissipation factor (Df) as measured in the range between 39 GHz, 80% RH. For example, the dielectric composite 200 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 200 may be any value between, and including, any of the values noted above. It will be further appreciated that the dissipation factor of the dielectric composite 200 may be within a range between, and including, any of the values noted above.

According to yet other embodiments, the dielectric composite 200 may have a particular dissipation factor (Df) as measured in the range between 76-81 GHz, 20% RH. For example, the dielectric composite 200 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 200 may be any value between, and including, any of the values noted above. It will be further appreciated that the dissipation factor of the dielectric composite 200 may be within a range between, and including, any of the values noted above.

According to yet other embodiments, the dielectric composite 200 may have a particular dissipation factor (Df) as measured in the range between 76-81 GHz, 80% RH. For example, the dielectric composite 200 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 200 may be any value between, and including, any of the values noted above. It will be further appreciated that the dissipation factor of the dielectric composite 200 may be within a range between, and including, any of the values noted above.

According to yet other embodiments, the dielectric composite 200 may have a particular coefficient of thermal expansion as measured according to IPC-TM-650 2.4.24 Rev. C Glass Transition Temperature and Z-Axis Thermal Expansion by TMA. For example, the dielectric composite 200 may have a coefficient of thermal expansion of not greater than about 80 ppm/° C.

According to yet other embodiments, the dielectric composite 200 may have a particular coefficient of thermal expansion as measured according to IPC-TM-650 2.4.24 Rev. C Glass Transition Temperature and X-Axis Thermal Expansion by TMA. For example, the dielectric composite 200 may have a coefficient of thermal expansion of not greater than about 80 ppm/° C.

According to yet other embodiments, the dielectric composite 200 may have a particular coefficient of thermal expansion as measured according to IPC-TM-650 2.4.24 Rev. C Glass Transition Temperature and Y-Axis Thermal Expansion by TMA. For example, the dielectric composite 200 may have a coefficient of thermal expansion of not greater than about 80 ppm/° C.

According to yet other embodiments, the dielectric composite 200 may have a particular tensile modulus as measured according to ASTM D882 or IPC-TM-650 2-4-18.3. For example, the dielectric composite 200 may have a tensile modulus of at least about 200 MPa, such as, at least about 300 MPa or at least about 400 MPa or at least about 500 MPa or at least about 600 MPa or at least about 700 MPa or at least about 800 MPa or at least about 900 MPa or at least about or even at least about 1000 MPa. According to still other embodiments, the dielectric composite 200 may have a tensile modulus of not greater than about 100000 MPa or not greater than about 90000 MPa or not greater than about 80000 MPa or not greater than about 70000 MPa or even not greater than about 60000 MPa. It will be appreciated that the tensile modulus of the dielectric composite 200 may be any value between, and including, any of the values noted above. It will be further appreciated that the tensile modulus of the dielectric composite 200 may be within a range between, and including, any of the values noted above.

According to yet other embodiments, the dielectric composite 200 may have a particular storage modulus at room temperature as measured according to IPC-TM-650 2.4.24.4. For example, the dielectric composite 200 may have a storage modulus at room temperature of at least about 1200 MPa, such as, at least about 1300 MPa or at least about 1400 MPa or at least about 1500 MPa or at least about 1600 MPa or at least about 1700 MPa or at least about 1800 MPa or at least about 1900 MPa or at least about 2000 MPa or at least about 3000 MPa or at least about 4000 MPa or at least about 4000 MPa or even at least about 5000 MPa. According to still other embodiments, the dielectric composite 200 may have a storage modulus at room temperature of not greater than about 100000 MPa or not greater than about 90000 MPa or not greater than about 80000 MPa or not greater than about 70000 MPa or even not greater than about 60000 MPa. It will be appreciated that the storage modulus at room temperature of the dielectric composite 200 may be any value between, and including, any of the values noted above. It will be further appreciated that the storage modulus at room temperature of the dielectric composite 200 may be within a range between, and including, any of the values noted above.

According to yet other embodiments, the dielectric composite 200 may have a particular storage modulus at 70° C. as measured according to IPC-TM-650 2.4.24.4. For example, the dielectric composite 200 may have a storage modulus at 70° C. of at least about 600 MPa, such as, at least about 800 MPa or at least about 1000 MPa or at least about 1200 MPa or at least about 1400 MPa or at least about 1600 MPa or at least about 1800 MPa or at least about 2000 MPa or at least about 3000 MPa or even at least about 4000 MPa. According to still other embodiments, the dielectric composite 200 may have a storage modulus at 70° C. of not greater than about 100000 MPa or not greater than about 90000 MPa or not greater than about 80000 MPa or not greater than about 70000 MPa or even not greater than about 60000 MPa. It will be appreciated that the storage modulus at 70° C. of the dielectric composite 200 may be any value between, and including, any of the values noted above. It will be further appreciated that the storage modulus at 70° C. of the dielectric composite 200 may be within a range between, and including, any of the values noted above.

According to yet other embodiments, the dielectric composite 200 may have a particular yield point as measured according to ASTM D882 OR IPC-TM-650 2-4-18.3. For example, the dielectric composite 200 may have a yield point of at least about 2 MPa, such as, at least about 3 MPa or at least about 4 MPa or at least about 5 MPa or at least about 6 MPa or even at least about 7 MPa. According to still other embodiments, the dielectric composite 200 may have a yield point of not greater than about 400 MPa or not greater than about 350 MPa or not greater than about 300 MPa or not greater than about 250 MPa or even not greater than about 200 MPa. It will be appreciated that the yield point of the dielectric composite 200 may be any value between, and including, any of the values noted above. It will be further appreciated that the yield point of the dielectric composite 200 may be within a range between, and including, any of the values noted above.

It will be appreciated that any dielectric composite or the dielectric substrate described herein (e.g. dielectric composite 200 or dielectric substrate 201) may include additional polymer based layers on the outer surfaces of the originally described dielectric substrate and that the additional polymer based layers may include filler (i.e. be filled polymer layers) as described herein or may not include fillers (i.e. be unfilled polymer layers).

It will be further appreciated that the dielectric composite 200 may further include an adhesive layer between reinforcement fabric layer and the dielectric substrate. According to particular embodiments, the adhesive layer may include PFA, FEP, or any combination thereof.

According to still other embodiments, the adhesive layer may have a particular thickness. For example, the adhesive layer may have thickness of at least about 0.1 microns, such as, at least about 0.2 microns or at least about 0.3 microns or at least about 0.4 microns or at least about 0.5 microns or at least about 0.6 microns or even at least about 0.7 microns. According to still other embodiments, the adhesive layer may have a thickness of not greater than about 25 microns, such as, not greater than about 20 microns or not greater than about 15 microns or not greater than about 10 microns or even not greater than about 5 microns. It will be appreciated that the thickness of the adhesive layer may be any value between, and including, any of the minimum and maximum values noted above. It will be further appreciated that the thickness of the adhesive layer may be within a range between, and including, any of the minimum and maximum values noted above.

Turning now to embodiments of copper-clad laminates that may include dielectric substrates described herein. Such additional embodiments described herein are generally directed to a copper-clad laminate that may include a copper foil layer and a dielectric substrate overlying the copper foil layer. According to certain embodiments, the dielectric substrate may include a resin matrix component, and a ceramic filler component.

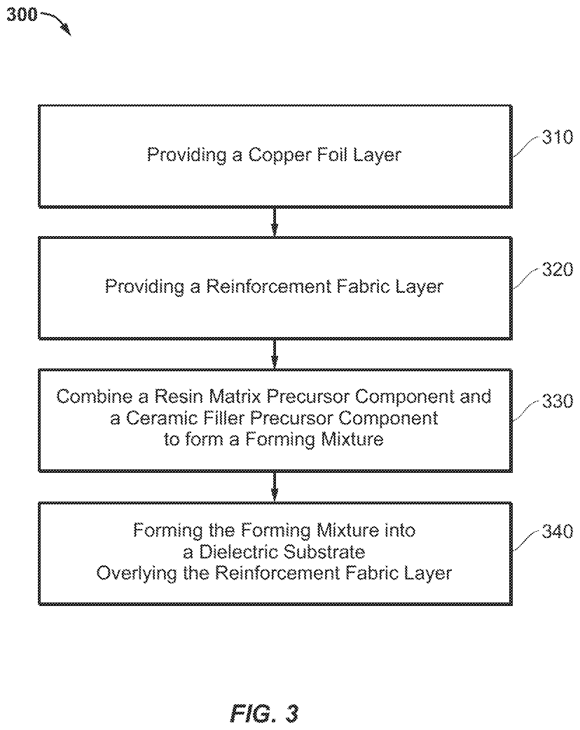

Referring next to a method of forming a copper-clad laminate, FIG. 3 includes a diagram showing a forming method 300 for forming a copper-clad laminate according to embodiments described herein. According to particular embodiments, the forming method 300 may include a first step 310 of providing a copper foil layer, a second step 320 of providing a reinforcement fabric layer overlying the copper foil layer, a third step 330 of combining a resin matrix precursor component and a ceramic filler precursor component to form a forming mixture, and a fourth step 340 of forming the forming mixture into a dielectric substrate overlying the reinforcement fabric layer to form the copper-clad laminate.

Referring first to the second step 320, according to particular embodiments, the reinforcement fabric layer may include a glass fabric material. According to still other embodiments, the reinforcement fabric layer may include E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof. According to still other embodiments, the reinforcement fabric layer may include a woven fabric or fibrous material. According to so yet other embodiments, the fibrous material may include E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof. According to yet other embodiments, the reinforcement fabric layer may include a non-woven fabric of fibrous material. According to so yet other embodiments, the fibrous material may include E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof.

According to still other embodiments, the reinforcement fabric layer may have a particular thickness. For example, the reinforcement fabric layer may have thickness of at least about 4 microns, such as, at least about 5 microns or at least 6 microns or at least about 7 microns or at least about 8 microns or at least about 9 microns or at least about 10 microns or at least about 11 microns or even at least about 12 microns. According to still other embodiments, the reinforcement fabric layer may have a thickness of not greater than about 1000 microns, such as, not greater than about 900 microns or not greater than about 800 microns or not greater than about 700 microns or not greater than about 600 microns or not greater than about 500 microns or not greater than about 400 microns or not greater than about 300 microns or even not greater than about 200 microns. It will be appreciated that the thickness of the reinforcement fabric layer may be any value between, and including, any of the minimum and maximum values noted above. It will be further appreciated that the thickness of the reinforcement fabric layer may be within a range between, and including, any of the minimum and maximum values noted above.

According to particular embodiments, the ceramic filler precursor component may include a first filler precursor material, which may have particular characteristics that may improve performance of the dielectric substrate formed by the forming method 300.

According to certain embodiments, the first filler precursor material may have a particular size distribution. For purposes of embodiments described herein, the particle size distribution of a material, for example, the particle size distribution of a first filler precursor material may be described using any combination of particle size distribution D-values D₁₀, D₅₀ and D₉₀. The D₁₀ value from a particle size distribution is defined as a particle size value where 10% of the particles are smaller than the value and 90% of the particles are larger than the value. The D₅₀ value from a particle size distribution is defined as a particle size value where 50% of the particles are smaller than the value and 50% of the particles are larger than the value. The D₉₀ value from a particle size distribution is defined as a particle size value where 90% of the particles are smaller than the value and 10% of the particles are larger than the value. For purposes of embodiments described herein, particle size measurements for a particular material are made using laser diffraction spectroscopy.

According to certain embodiments, the first filler precursor material may have a particular size distribution D₁₀ value. For example, the D₁₀ of the first filler precursor material may be at least about 0.5 microns, such as, at least about 0.6 microns or at least about 0.7 microns or at least about 0.8 microns or at least about 0.9 microns or at least about 1.0 microns or at least about 1.1 microns or even at least about 1.2 microns. According to still other embodiments, the D₁₀ of the first filler material may be not greater than about 1.6 microns, such as, not greater than about 1.5 microns or even not greater than about 1.4 microns. It will be appreciated that the D₁₀ of the first filler precursor material may be any value between, and including, any of the minimum and maximum values noted above. It will be further appreciated that the D₁₀ of the first filler precursor material may be within a range between, and including, any of the minimum and maximum values noted above.

According to other embodiments, the first filler precursor material may have a particular size distribution D₅₀ value. For example, the D₅₀ of the first filler precursor material may be at least about 0.8 microns, such as, at least about 0.9 microns or at least about 1.0 microns or at least about 1.1 microns or at least about 1.2 microns or at least about 1.3 microns or at least about 1.4 microns or at least about 1.5 microns or at least about 1.6 microns or at least about 1.7 microns or at least about 1.8 microns or at least about 1.9 microns or at least about 2.0 microns or at least about 2.1 microns or even at least about 2.2 microns. According to still other embodiments, the D₅₀ of the first filler material may be not greater than about 2.7 microns, such as, not greater than about 2.6 microns or not greater than about 2.5 microns or even not greater than about 2.4. It will be appreciated that the D₅₀ of the first filler precursor material may be any value between, and including, any of the minimum and maximum values noted above. It will be further appreciated that the D₅₀ of the first filler precursor material may be within a range between, and including, any of the minimum and maximum values noted above.

According to other embodiments, the first filler precursor material may have a particular size distribution D₉₀ value. For example, the D₉₀ of the first filler precursor material may be at least about 1.5 microns, such as, at least about 1.6 microns or at least about 1.7 microns or at least about 1.8 microns or at least about 1.9 microns or at least about 2.0 microns or at least about 2.1 microns or at least about 2.2 microns or at least about 2.3 microns or at least about 2.2 microns or at least about 2.5 microns or at least about 2.6 microns or even at least about 2.7 microns. According to still other embodiments, the D₉₀ of the first filler material may be not greater than about 8.0 microns, such as, not greater than about 7.5 microns or not greater than about 7.0 microns or not greater than about 6.5 microns or not greater than about 6.0 microns or not greater than about 5.5 microns or not greater than about 5.4 microns or not greater than about 5.3 microns or not greater than about 5.2 or even not greater than about 5.1 microns. It will be appreciated that the D₉₀ of the first filler precursor material may be any value between, and including, any of the minimum and maximum values noted above. It will be further appreciated that the D₉₀ of the first filler precursor material may be within a range between, and including, any of the minimum and maximum values noted above.

According to still other embodiments, the first filler precursor material may have a particular mean particle size as measured using laser diffraction spectroscopy. For example, the mean particle size of the first filler precursor material may be not greater than about 10 microns, such as, not greater than about 9 microns or not greater than about 8 microns or not greater than about 7 microns or not greater than about 6 microns or not greater than about 5 microns or not greater than about 4 microns or not greater than about 3 microns or even not greater than about 2 microns. It will be appreciated that the mean particle size of the first filler precursor material may be any value between, and including, any of the values noted above. It will be further appreciated that the mean particle size of the first filler precursor material may be within a range between, and including, any of the values noted above.

According to still other embodiments, the first filler precursor material may be described as having a particular particle size distribution span (PSDS), where the PSDS is equal to (D₉₀−D₁₀)/D₅₀, where D₉₀ is equal to a D₉₀ particle size distribution measurement of the first filler precursor material, D₁₀ is equal to a D₁₀ particle size distribution measurement of the first filler precursor material, and D₅₀ is equal to a D₅₀ particle size distribution measurement of the first filler precursor material. For example, the PSDS of the first filler precursor material may be not greater than about 5, such as, not greater than about 4.5 or not greater than about 4.0 or not greater than about 3.5 or not greater than about 3.0 or even not greater than about 2.5. It will be appreciated that the PSDS of the first filler precursor material may be any value between, and including, any of the values noted above. It will be further appreciated that the PSDS of the first filler precursor material may be within a range between, and including, any of the values noted above.

According to still other embodiments, the first filler precursor material may be described as having a particular average surface area as measured using Brunauer-Emmett-Teller (BET) surface area analysis (Nitrogen Adsorption). For example, the first filler precursor material may have an average surface area of not greater than about 8 m²/g, such as, not greater than about 7.9 m²/g or not greater than about 7.5 m²/g or not greater than about 7.0 m²/g or not greater than about 6.5 m²/g or not greater than about 6.0 m²/g or not greater than about 5.5 m²/g or not greater than about 5.0 m²/g or not greater than about 4.5 m²/g or not greater than about 4.0 m²/g or even not greater than about 3.5 m²/g. According to still other embodiments, the first filler precursor material may have an average surface area of at least about 1.2 m²/g, such as, at least about 2.2 m²/g. It will be appreciated that the average surface area of the first filler precursor material may be any value between, and including, any of the minimum and maximum values noted above. It will be further appreciated that the average surface area of the first filler precursor material may be within a range between, and including, any of the minimum and maximum values noted above.

According to other embodiments, the first filler precursor material may include a particular material. According to particular embodiments, the first filler precursor material may include a silica-based compound. According to still other embodiments, the first filler precursor material may consist of a silica-based compound. According to other embodiments, the first filler precursor material may include silica. According to still other embodiments, the first filler precursor material may consist of silica.

According to yet other embodiments, the forming mixture may include a particular content of the ceramic filler precursor component. For example, the content of the ceramic filler precursor component may be at least about 45 vol. % for a total volume of the forming mixture, such as, at least about 46 vol. % or at least about 47 vol. % or at least about 48 vol. % or at least about 49 vol. % or at least about 50 vol. % or at least about 51 vol. % or at least about 52 vol. % or at least about 53 vol. % or even at least about 54 vol. %. According to still other embodiments, the content of the ceramic filler precursor component may be not greater than about 57 vol. % for a total volume of the forming mixture, such as, not greater than about 56 vol. % or even not greater than about 55 vol. %. It will be appreciated that the content of the ceramic filler precursor component may be any value between, and including, any of the minimum and maximum values noted above. It will be further appreciated that the content of the ceramic filler precursor component may be within a range between, and including, any of the minimum and maximum values noted above.

According to still other embodiments, the ceramic filler precursor component may include a particular content of the first filler precursor material. For example, the content of the first filler precursor material may be at least about 80 vol. % for a total volume of the ceramic filler precursor component, such as, at least about 81 vol. % or at least about 82 vol. % or at least about 83 vol. % or at least about 84 vol. % or at least about 85 vol. % or at least about 86 vol. % or at least about 87 vol. % or at least about 88 vol. % or at least about 89 vol. % or even at least about 90 vol. %. According to still other embodiments, the content of the first filler precursor material may be not greater than about 100 vol. % for a total volume of the ceramic filler precursor component, such as, not greater than about 99 vol. % or not greater than about 98 vol. % or not greater than about 97 vol. % or not greater than about 96 vol. % or not greater than about 95 vol. % or not greater than about 94 vol. % or not greater than about 93 vol. % or even not greater than about 92 vol. %. It will be appreciated that the content of the first filler precursor material may be any value between, and including, any of the minimum and maximum values noted above. It will be further appreciated that the content of the first filler precursor material may be within a range between, and including, any of the minimum and maximum values noted above.

According to still other embodiments, the ceramic filler precursor component may include a second filler precursor material.

According to yet other embodiments, the second filler precursor material may include a particular material. For example, the second filler precursor material may include a high dielectric constant ceramic material, such as, a ceramic material having a dielectric constant of at least about 14. According to particular embodiments, the second filler precursor material may include any high dielectric constant ceramic material, such as, TiO₂, SrTiO₃, ZrTi₂O₆, MgTiO₃, CaTiO₃, BaTiO₄ or any combination thereof.

According to yet other embodiments, the second filler precursor material may include TiO₂. According to still other embodiments, the second filler precursor material may consist of TiO₂.

According to still other embodiments, the ceramic filler precursor component may include a particular content of the second filler precursor material. For example, the content of the second filler precursor material may be at least about 1 vol. % for a total volume of the ceramic filler precursor component, such as, at least about 2 vol. % or at least about 3 vol. % or at least about 4 vol. % or at least about 5 vol. % or at least about 6 vol. % or at least about 7 vol. % or at least about 8 vol. % or at least about 9 vol. % or at least about 10 vol. %. According to still other embodiments, the content of the second filler precursor material may be not greater than about 20 vol. % for a total volume of the ceramic filler precursor component, such as, not greater than about 19 vol. % or not greater than about 18 vol. % or not greater than about 17 vol. % or not greater than about 16 vol. % or not greater than about 15 vol. % or not greater than about 14 vol. % or not greater than about 13 vol. % or not greater than about 12 vol. %. It will be appreciated that the content of the second filler precursor material may be any value between, and including, any of the minimum and maximum values noted above. It will be further appreciated that the content of the second filler precursor material may be within a range between, and including, any of the minimum and maximum values noted above.

According to yet other embodiments, the ceramic filler precursor component may include a particular content of amorphous material. For example, the ceramic filler precursor component may include at least about 97% amorphous material, such as, at least about 98% or even at least about 99%. It will be appreciated that the content of amorphous material may be any value between, and including, any of the values noted above. It will be further appreciated that the content of the content of amorphous material may be within a range between, and including, any of the values noted above.

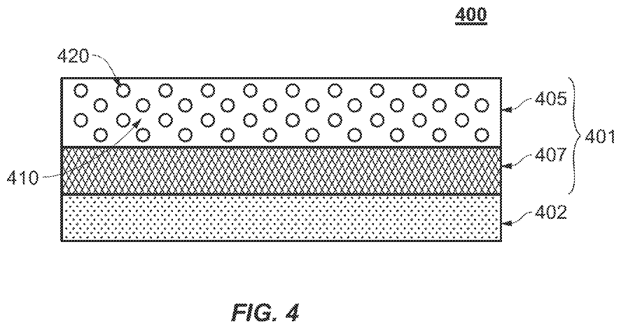

Referring now to embodiments of the copper-clad laminate formed according to forming method 300, FIG. 4 includes diagram of a copper-clad lamination 400. As shown in FIG. 4, the copper-clad laminate 400 may include a copper foil layer 402, and a dielectric composite 401 overlying a surface of the copper foil layer 402. According to certain embodiments, the dielectric composite 401 may include a dielectric substrate 405 overlying a reinforcement fabric layer 407. According to still other embodiments, the dielectric substrate 405 may include a resin matrix component 410 and a ceramic filler component 420.

According to particular embodiments, the reinforcement fabric layer 407 may include a glass fabric material. According to still other embodiments, the reinforcement fabric layer 407 may include E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof. According to still other embodiments, the reinforcement fabric layer 407 may include a woven fabric or fibrous material. According to so yet other embodiments, the fibrous material may include E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof. According to yet other embodiments, the reinforcement fabric layer 407 may include a non-woven fabric of fibrous material. According to so yet other embodiments, the fibrous material may include E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof.

According to still other embodiments, the reinforcement fabric layer 407 may have a particular thickness. For example, the reinforcement fabric layer 407 may have thickness of at least about 4 microns, such as, at least about 5 microns or at least 6 microns or at least about 7 microns or at least about 8 microns or at least about 9 microns or at least about 10 microns or at least about 11 microns or even at least about 12 microns. According to still other embodiments, the reinforcement fabric layer 407 may have a thickness of not greater than about 1000 microns, such as, not greater than about 900 microns or not greater than about 800 microns or not greater than about 700 microns or not greater than about 600 microns or not greater than about 500 microns or not greater than about 400 microns or not greater than about 300 microns or even not greater than about 200 microns. It will be appreciated that the thickness of the reinforcement fabric layer 407 may be any value between, and including, any of the minimum and maximum values noted above. It will be further appreciated that the thickness of the reinforcement fabric layer 407 may be within a range between, and including, any of the minimum and maximum values noted above.

According to particular embodiments, the ceramic filler component 420 may include a first filler material, which may have particular characteristics that may improve performance of the copper-clad laminate 400.

According to certain embodiments, the first filler material of the ceramic filler component 420 may have a particular size distribution. For purposes of embodiments described herein, the particle size distribution of a material, for example, the particle size distribution of a first filler material may be described using any combination of particle size distribution D-values D₁₀, D₅₀ and D₉₀. The D₁₀ value from a particle size distribution is defined as a particle size value where 10% of the particles are smaller than the value and 90% of the particles are larger than the value. The D₅₀ value from a particle size distribution is defined as a particle size value where 50% of the particles are smaller than the value and 50% of the particles are larger than the value. The D₉₀ value from a particle size distribution is defined as a particle size value where 90% of the particles are smaller than the value and 10% of the particles are larger than the value. For purposes of embodiments described herein, particle size measurements for a particular material are made using laser diffraction spectroscopy.

According to certain embodiments, the first filler material of the ceramic filler component 420 may have a particular size distribution D₁₀ value. For example, the D₁₀ of the first filler material may be at least about 0.5 microns, such as, at least about 0.6 microns or at least about 0.7 microns or at least about 0.8 microns or at least about 0.9 microns or at least about 1.0 microns or at least about 1.1 microns or even at least about 1.2 microns. According to still other embodiments, the D₁₀ of the first filler material may be not greater than about 1.6 microns, such as, not greater than about 1.5 microns or even not greater than about 1.4 microns. It will be appreciated that the D₁₀ of the first filler material may be any value between, and including, any of the minimum and maximum values noted above. It will be further appreciated that the D₁₀ of the first filler material may be within a range between, and including, any of the minimum and maximum values noted above.

According to other embodiments, the first filler material of the ceramic filler component 420 may have a particular size distribution D₅₀ value. For example, the D₅₀ of the first filler material may be at least about 0.8 microns, such as, at least about 0.9 microns or at least about 1.0 microns or at least about 1.1 microns or at least about 1.2 microns or at least about 1.3 microns or at least about 1.4 microns or at least about 1.5 microns or at least about 1.6 microns or at least about 1.7 microns or at least about 1.8 microns or at least about 1.9 microns or at least about 2.0 microns or at least about 2.1 microns or even at least about 2.2 microns. According to still other embodiments, the D₅₀ of the first filler material may be not greater than about 2.7 microns, such as, not greater than about 2.6 microns or not greater than about 2.5 microns or even not greater than about 2.4. It will be appreciated that the D₅₀ of the first filler material may be any value between, and including, any of the minimum and maximum values noted above. It will be further appreciated that the D₅₀ of the first filler material may be within a range between, and including, any of the minimum and maximum values noted above.

According to other embodiments, the first filler material of the ceramic filler component 420 may have a particular size distribution D₉₀ value. For example, the D₉₀ of the first filler material may be at least about 1.5 microns, such as, at least about 1.6 microns or at least about 1.7 microns or at least about 1.8 microns or at least about 1.9 microns or at least about 2.0 microns or at least about 2.1 microns or at least about 2.2 microns or at least about 2.3 microns or at least about 2.2 microns or at least about 2.5 microns or at least about 2.6 microns or even at least about 2.7 microns. According to still other embodiments, the D₉₀ of the first filler material may be not greater than about 8.0 microns, such as, not greater than about 7.5 microns or not greater than about 7.0 microns or not greater than about 6.5 microns or not greater than about 6.0 microns or not greater than about 5.5 microns or not greater than about 5.4 microns or not greater than about 5.3 microns or not greater than about 5.2 or even not greater than about 5.1 microns. It will be appreciated that the D₉₀ of the first filler material may be any value between, and including, any of the minimum and maximum values noted above. It will be further appreciated that the D₉₀ of the first filler material may be within a range between, and including, any of the minimum and maximum values noted above.

According to still other embodiments, the first filler material of the ceramic filler component 420 may have a particular mean particle size as measured according to laser diffraction spectroscopy. For example, the mean particle size of the first filler material may be not greater than about 10 microns, such as, not greater than about 9 microns or not greater than about 8 microns or not greater than about 7 microns or not greater than about 6 microns or not greater than about 5 microns or not greater than about 4 microns or not greater than about 3 microns or even not greater than about 2 microns. It will be appreciated that the mean particle size of the first filler material may be any value between, and including, any of the values noted above. It will be further appreciated that the mean particle size of the first filler material may be within a range between, and including, any of the values noted above.

According to still other embodiments, the first filler material of the ceramic filler component 420 may be described as having a particular particle size distribution span (PSDS), where the PSDS is equal to (D₉₀−D₁₀)/D₅₀, where D₉₀ is equal to a D₉₀ particle size distribution measurement of the first filler material, D₁₀ is equal to a D₁₀ particle size distribution measurement of the first filler material, and D₅₀ is equal to a D₅₀ particle size distribution measurement of the first filler material. For example, the PSDS of the first filler material may be not greater than about 5, such as, not greater than about 4.5 or not greater than about 4.0 or not greater than about 3.5 or not greater than about 3.0 or even not greater than about 2.5. It will be appreciated that the PSDS of the first filler material may be any value between, and including, any of the values noted above. It will be further appreciated that the PSDS of the first filler material may be within a range between, and including, any of the values noted above.

According to still other embodiments, the first filler material of the ceramic filler component 420 may be described as having a particular average surface area as measured using Brunauer-Emmett-Teller (BET) surface area analysis (Nitrogen Adsorption). For example, the first filler material may have an average surface area of not greater than about 8 m²/g, such as, not greater than about 7.9 m²/g or not greater than about 7.5 m²/g or not greater than about 7.0 m²/g or not greater than about 6.5 m²/g or not greater than about 6.0 m²/g or not greater than about 5.5 m²/g or not greater than about 5.0 m²/g or not greater than about 4.5 m²/g or not greater than about 4.0 m²/g or even not greater than about 3.5 m²/g. According to still other embodiments, the first filler material may have an average surface area of at least about 1.2 m²/g, such as, at least about 2.2 m²/g. It will be appreciated that the average surface area of the first filler material may be any value between, and including, any of the minimum and maximum values noted above. It will be further appreciated that the average surface area of the first filler material may be within a range between, and including, any of the minimum and maximum values noted above.

According to other embodiments, the first filler material of the ceramic filler component 420 may include a particular material. According to particular embodiments, the first filler material may include a silica-based compound. According to still other embodiments, the first filler material may consist of a silica-based compound. According to other embodiments, the first filler material may include silica. According to still other embodiments, the first filler material may consist of silica.

According to yet other embodiments, the dielectric substrate 405 may include a particular content of the ceramic filler component 420. For example, the content of the ceramic filler component 420 may be at least about 45 vol. % for a total volume of the dielectric substrate 405, such as, at least about 46 vol. % or at least about 47 vol. % or at least about 48 vol. % or at least about 49 vol. % or at least about 50 vol. % or at least about 51 vol. % or at least about 52 vol. % or at least about 53 vol. % or even at least about 54 vol. %. According to still other embodiments, the content of the ceramic filler component 420 may be not greater than about 57 vol. % for a total volume of the dielectric substrate 400, such as, not greater than about 56 vol. % or even not greater than about 55 vol. %. It will be appreciated that the content of the ceramic filler component 420 may be any value between, and including, any of the minimum and maximum values noted above. It will be further appreciated that the content of the ceramic filler component 420 may be within a range between, and including, any of the minimum and maximum values noted above.

According to still other embodiments, the ceramic filler component 420 may include a particular content of the first filler material. For example, the content of the first filler material may be at least about 80 vol. % for a total volume of the ceramic filler component 420, such as, at least about 81 vol. % or at least about 82 vol. % or at least about 83 vol. % or at least about 84 vol. % or at least about 85 vol. % or at least about 86 vol. % or at least about 87 vol. % or at least about 88 vol. % or at least about 89 vol. % or even at least about 90 vol. %. According to still other embodiments, the content of the first filler material may be not greater than about 100 vol. % for a total volume of the ceramic filler component 220, such as, not greater than about 99 vol. % or not greater than about 98 vol. % or not greater than about 97 vol. % or not greater than about 96 vol. % or not greater than about 95 vol. % or not greater than about 94 vol. % or not greater than about 93 vol. % or even not greater than about 92 vol. %. It will be appreciated that the content of the first filler material may be any value between, and including, any of the minimum and maximum values noted above. It will be further appreciated that the content of the first filler material may be within a range between, and including, any of the minimum and maximum values noted above.

According to still other embodiments, the ceramic filler component 420 may include a second filler material.

According to yet other embodiments, the second filler material of the ceramic filler component 420 may include a particular material. For example, the second filler material may include a high dielectric constant ceramic material, such as, a ceramic material having a dielectric constant of at least about 14. According to particular embodiments, the second filler material of the ceramic filler component 420 may include any high dielectric constant ceramic material, such as, TiO₂, SrTiO₃, ZrTi₂O₆, MgTiO₃, CaTiO₃, BaTiO₄ or any combination thereof.

According to yet other embodiments, the second filler material of the ceramic filler component 420 may include TiO₂. According to still other embodiments, the second filler material may consist of TiO₂.

According to still other embodiments, the ceramic filler component 420 may include a particular content of the second filler material. For example, the content of the second filler material may be at least about 1 vol. % for a total volume of the ceramic filler component 420, such as, at least about 2 vol. % or at least about 3 vol. % or at least about 4 vol. % or at least about 5 vol. % or at least about 6 vol. % or at least about 7 vol. % or at least about 8 vol. % or at least about 9 vol. % or at least about 10 vol. %. According to still other embodiments, the content of the second filler material may be not greater than about 20 vol. % for a total volume of the ceramic filler component 220, such as, not greater than about 19 vol. % or not greater than about 18 vol. % or not greater than about 17 vol. % or not greater than about 16 vol. % or not greater than about 15 vol. % or not greater than about 14 vol. % or not greater than about 13 vol. % or not greater than about 12 vol. %. It will be appreciated that the content of the second filler material may be any value between, and including, any of the minimum and maximum values noted above. It will be further appreciated that the content of the second filler material may be within a range between, and including, any of the minimum and maximum values noted above.

According to yet other embodiments, the ceramic filler component 420 may include a particular content of amorphous material. For example, the ceramic filler component 420 may include at least about 97% amorphous material, such as, at least about 98% or even at least about 99%. It will be appreciated that the content of amorphous material may be any value between, and including, any of the values noted above. It will be further appreciated that the content of the content of amorphous material may be within a range between, and including, any of the values noted above.

According to other embodiments, the resin matrix component 410 may include a particular material. For example, the resin matrix component 410 may include a perfluoropolymer. According to still other embodiments, the resin matrix component 410 may consist of a perfluoropolymer.

According to yet other embodiments, the perfluoropolymer of the resin matrix component 410 may include a copolymer of tetrafluoroethylene (TFE); a copolymer of hexafluoropropylene (HFP); a terpolymer of tetrafluoroethylene (TFE); or any combination thereof. According to other embodiments, the perfluoropolymer of the resin matrix component 410 may consist of a copolymer of tetrafluoroethylene (TFE); a copolymer of hexafluoropropylene (HFP); a terpolymer of tetrafluoroethylene (TFE); or any combination thereof.

According to yet other embodiments, the perfluoropolymer of the resin matrix component 410 may include polytetrafluoroethylene (PTFE), perfluoroalkoxy polymer resin (PFA), fluorinated ethylene propylene (FEP), or any combination thereof. According to still other embodiments, the perfluoropolymer of the resin matrix component 410 may consist of polytetrafluoroethylene (PTFE), perfluoroalkoxy polymer resin (PFA), fluorinated ethylene propylene (FEP), or any combination thereof.

According to yet other embodiments, the dielectric substrate 400 may include a particular content of the resin matrix component 410. For example, the content of the resin matrix component 410 may be at least about 45 vol. % for a total volume of the dielectric substrate 400, such as, at least about 46 vol. % or at least about 47 vol. % or at least about 48 vol. % or at least about 49 vol. % or at least about 50 vol. % or at least about 51 vol. % or at least about 52 vol. % or at least about 53 vol. % or at least about 54 vol. % or even at least about 55 vol. %. According to still other embodiments, the content of the resin matrix component 410 is not greater than about 63 vol. % for a total volume of the dielectric substrate 400 or not greater than about 62 vol. % or not greater than about 61 vol. % or not greater than about 60 vol. % or not greater than about 59 vol. % or not greater than about 58 vol. % or even not greater than about 57 vol. %. It will be appreciated that the content of the resin matrix component 410 may be any value between, and including, any of the minimum and maximum values noted above. It will be further appreciated that the content of the resin matrix component 410 may be within a range between, and including, any of the minimum and maximum values noted above.

According to yet other embodiments, the dielectric substrate 405 may include a particular content of the perfluoropolymer. For example, the content of the perfluoropolymer may be at least about 45 vol. % for a total volume of the dielectric substrate 405, such as, at least about 46 vol. % or at least about 47 vol. % or at least about 48 vol. % or at least about 49 vol. % or at least about 50 vol. % or at least about 51 vol. % or at least about 52 vol. % or at least about 53 vol. % or at least about 54 vol. % or even at least about 55 vol. %. According to still other embodiments, the content of the perfluoropolymer may be not greater than about 63 vol. % for a total volume of the dielectric substrate 201, such as, not greater than about 62 vol. % or not greater than about 61 vol. % or not greater than about 60 vol. % or not greater than about 59 vol. % or not greater than about 58 vol. % or even not greater than about 57 vol. %. It will be appreciated that the content of the perfluoropolymer may be any value between, and including, any of the minimum and maximum values noted above. It will be further appreciated that the content of the perfluoropolymer may be within a range between, and including, any of the minimum and maximum values noted above.

According to still other embodiments, the dielectric substrate 405 may include a particular porosity as measured using x-ray diffraction. For example, the porosity of the substrate 405 may be not greater than about 10 vol. %, such as, not greater than about 9 vol. % or not greater than about 8 vol. % or not greater than about 7 vol. % or not greater than about 6 vol. % or even not greater than about 5 vol. %. It will be appreciated that the porosity of the dielectric substrate 405 may be any value between, and including, any of the values noted above. It will be further appreciated that the porosity of the dielectric substrate 405 may be within a range between, and including, any of the values noted above.

According to yet other embodiments, the dielectric substrate 405 may have a particular average thickness. For example, the average thickness of the dielectric substrate 405 may be at least about 10 microns, such as, at least about 15 microns or at least about 20 microns or at least about 25 microns or at least about 30 microns or at least about 35 microns or at least about 40 microns or at least about 45 microns or at least about 50 microns or at least about 55 microns or at least about 60 microns or at least about 65 microns or at least about 70 microns or even at least about 75 microns. According to yet other embodiments, the average thickness of the dielectric substrate 405 may be not greater than about 2000 microns, such as, not greater than about 1800 microns or not greater than about 1600 microns or not greater than about 1400 microns or not greater than about 1200 microns or not greater than about 1000 microns or not greater than about 800 microns or not greater than about 600 microns or not greater than about 400 microns or not greater than about 200 microns or not greater than about 190 microns or not greater than about 180 microns or not greater than about 170 microns or not greater than about 160 microns or not greater than about 150 microns or not greater than about 140 microns or not greater than about 120 microns or even not greater than about 100 microns. It will be appreciated that the average thickness of the dielectric substrate 405 may be any value between, and including, any of the minimum and maximum values noted above. It will be further appreciated that the average thickness of the dielectric substrate 405 may be within a range between, and including, any of the minimum and maximum values noted above.

According to yet other embodiments, the dielectric substrate 405 may have a particular dissipation factor (Df) as measured in the range between 5 GHz, 20% RH. For example, the dielectric substrate 405 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 405 may be any value between, and including, any of the values noted above. It will be further appreciated that the dissipation factor of the dielectric substrate 405 may be within a range between, and including, any of the values noted above.

According to yet other embodiments, the dielectric substrate 405 may have a particular dissipation factor (Df) as measured in the range between 5 GHz, 80% RH. For example, the dielectric substrate 405 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 405 may be any value between, and including, any of the values noted above. It will be further appreciated that the dissipation factor of the dielectric substrate 405 may be within a range between, and including, any of the values noted above.

According to yet other embodiments, the dielectric substrate 405 may have a particular dissipation factor (Df) as measured in the range between 10 GHz, 20% RH. For example, the dielectric substrate 405 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 405 may be any value between, and including, any of the values noted above. It will be further appreciated that the dissipation factor of the dielectric substrate 405 may be within a range between, and including, any of the values noted above.

According to yet other embodiments, the dielectric substrate 405 may have a particular dissipation factor (Df) as measured in the range between 10 GHz, 80% RH. For example, the dielectric substrate 405 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 405 may be any value between, and including, any of the values noted above. It will be further appreciated that the dissipation factor of the dielectric substrate 405 may be within a range between, and including, any of the values noted above.

According to yet other embodiments, the dielectric substrate 405 may have a particular dissipation factor (Df) as measured in the range between 28 GHz, 20% RH. For example, the dielectric substrate 405 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 405 may be any value between, and including, any of the values noted above. It will be further appreciated that the dissipation factor of the dielectric substrate 405 may be within a range between, and including, any of the values noted above.

According to yet other embodiments, the dielectric substrate 405 may have a particular dissipation factor (Df) as measured in the range between 28 GHz, 80% RH. For example, the dielectric substrate 405 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 405 may be any value between, and including, any of the values noted above. It will be further appreciated that the dissipation factor of the dielectric substrate 405 may be within a range between, and including, any of the values noted above.

According to yet other embodiments, the dielectric substrate 405 may have a particular dissipation factor (Df) as measured in the range between 39 GHz, 20% RH. For example, the dielectric substrate 405 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 405 may be any value between, and including, any of the values noted above. It will be further appreciated that the dissipation factor of the dielectric substrate 405 may be within a range between, and including, any of the values noted above.

According to yet other embodiments, the dielectric substrate 405 may have a particular dissipation factor (Df) as measured in the range between 39 GHz, 80% RH. For example, the dielectric substrate 405 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 405 may be any value between, and including, any of the values noted above. It will be further appreciated that the dissipation factor of the dielectric substrate 405 may be within a range between, and including, any of the values noted above.

According to yet other embodiments, the dielectric substrate 405 may have a particular dissipation factor (Df) as measured in the range between 76-81 GHz, 20% RH. For example, the dielectric substrate 405 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 405 may be any value between, and including, any of the values noted above. It will be further appreciated that the dissipation factor of the dielectric substrate 405 may be within a range between, and including, any of the values noted above.

According to yet other embodiments, the dielectric substrate 405 may have a particular dissipation factor (Df) as measured in the range between 76-81 GHz, 80% RH. For example, the dielectric substrate 405 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric substrate 405 may be any value between, and including, any of the values noted above. It will be further appreciated that the dissipation factor of the dielectric substrate 405 may be within a range between, and including, any of the values noted above.

According to yet other embodiments, the dielectric substrate 405 may have a particular coefficient of thermal expansion as measured according to IPC-TM-650 2.4.24 Rev. C Glass Transition Temperature and Z-Axis Thermal Expansion by TMA. For example, the dielectric substrate 405 may have a coefficient of thermal expansion of not greater than about 80 ppm/° C.

According to yet other embodiments, the dielectric substrate 405 may have a particular coefficient of thermal expansion as measured according to IPC-TM-650 2.4.24 Rev. C Glass Transition Temperature and X-Axis Thermal Expansion by TMA. For example, the dielectric substrate 405 may have a coefficient of thermal expansion of not greater than about 80 ppm/° C.

According to yet other embodiments, the dielectric substrate 405 may have a particular coefficient of thermal expansion as measured according to IPC-TM-650 2.4.24 Rev. C Glass Transition Temperature and Y-Axis Thermal Expansion by TMA. For example, the dielectric substrate 405 may have a coefficient of thermal expansion of not greater than about 80 ppm/° C.

According to yet other embodiments, the dielectric composite 401 may have a particular dissipation factor (Df) as measured in the range between 5 GHz, 20% RH. For example, the dielectric composite 401 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 401 may be any value between, and including, any of the values noted above. It will be further appreciated that the dissipation factor of the dielectric composite 401 may be within a range between, and including, any of the values noted above.

According to yet other embodiments, the dielectric composite 401 may have a particular dissipation factor (Df) as measured in the range between 5 GHz, 80% RH. For example, the dielectric composite 401 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 401 may be any value between, and including, any of the values noted above. It will be further appreciated that the dissipation factor of the dielectric composite 401 may be within a range between, and including, any of the values noted above.

According to yet other embodiments, the dielectric composite 401 may have a particular dissipation factor (Df) as measured in the range between 10 GHz, 20% RH. For example, the dielectric composite 401 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 401 may be any value between, and including, any of the values noted above. It will be further appreciated that the dissipation factor of the dielectric composite 401 may be within a range between, and including, any of the values noted above.

According to yet other embodiments, the dielectric composite 401 may have a particular dissipation factor (Df) as measured in the range between 10 GHz, 80% RH. For example, the dielectric composite 401 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 401 may be any value between, and including, any of the values noted above. It will be further appreciated that the dissipation factor of the dielectric composite 401 may be within a range between, and including, any of the values noted above.

According to yet other embodiments, the dielectric composite 401 may have a particular dissipation factor (Df) as measured in the range between 28 GHz, 20% RH. For example, the dielectric composite 401 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 401 may be any value between, and including, any of the values noted above. It will be further appreciated that the dissipation factor of the dielectric composite 401 may be within a range between, and including, any of the values noted above.

According to yet other embodiments, the dielectric composite 401 may have a particular dissipation factor (Df) as measured in the range between 28 GHz, 80% RH. For example, the dielectric composite 401 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 401 may be any value between, and including, any of the values noted above. It will be further appreciated that the dissipation factor of the dielectric composite 401 may be within a range between, and including, any of the values noted above.

According to yet other embodiments, the dielectric composite 401 may have a particular dissipation factor (Df) as measured in the range between 39 GHz, 20% RH. For example, the dielectric composite 401 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 401 may be any value between, and including, any of the values noted above. It will be further appreciated that the dissipation factor of the dielectric composite 401 may be within a range between, and including, any of the values noted above.

According to yet other embodiments, the dielectric composite 401 may have a particular dissipation factor (Df) as measured in the range between 39 GHz, 80% RH. For example, the dielectric composite 401 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 401 may be any value between, and including, any of the values noted above. It will be further appreciated that the dissipation factor of the dielectric composite 401 may be within a range between, and including, any of the values noted above.

According to yet other embodiments, the dielectric composite 401 may have a particular dissipation factor (Df) as measured in the range between 76-81 GHz, 20% RH. For example, the dielectric composite 401 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 401 may be any value between, and including, any of the values noted above. It will be further appreciated that the dissipation factor of the dielectric composite 401 may be within a range between, and including, any of the values noted above.

According to yet other embodiments, the dielectric composite 401 may have a particular dissipation factor (Df) as measured in the range between 76-81 GHz, 80% RH. For example, the dielectric composite 401 may have a dissipation factor of not greater than about 0.005, such as, not greater than about 0.004 or not greater than about 0.003 or not greater than about 0.002 or not greater than about 0.0019 or not greater than about 0.0018 or not greater than about 0.0017 or not greater than about 0.0016 or not greater than about 0.0015 or not greater than about 0.0014. It will be appreciated that the dissipation factor of the dielectric composite 401 may be any value between, and including, any of the values noted above. It will be further appreciated that the dissipation factor of the dielectric composite 401 may be within a range between, and including, any of the values noted above.

It will be appreciated that any copper-clad laminate described herein may include additional polymer-based layers on the outer surfaces of the originally described dielectric substrate between the substrate and any copper foil layer of the copper-clad laminate. As also noted herein, the additional polymer-based layers may include filler (i.e., be filled polymer layers) as described herein or may not include fillers (i.e., be unfilled polymer layers).

It will be further appreciated that the dielectric composite 401 may further include an adhesive layer between reinforcement fabric layer and the dielectric substrate. According to particular embodiments, the adhesive layer may include PFA, FEP, or any combination thereof.

According to still other embodiments, the adhesive layer may have a particular thickness. For example, the adhesive layer may have thickness of at least about 0.1 microns, such as, at least about 0.2 microns or at least about 0.3 microns or at least about 0.4 microns or at least about 0.5 microns or at least about 0.6 microns or even at least about 0.7 microns. According to still other embodiments, the adhesive layer may have a thickness of not greater than about 25 microns, such as, not greater than about 20 microns or not greater than about 15 microns or not greater than about 10 microns or even not greater than about 5 microns. It will be appreciated that the thickness of the adhesive layer may be any value between, and including, any of the minimum and maximum values noted above. It will be further appreciated that the thickness of the adhesive layer may be within a range between, and including, any of the minimum and maximum values noted above.

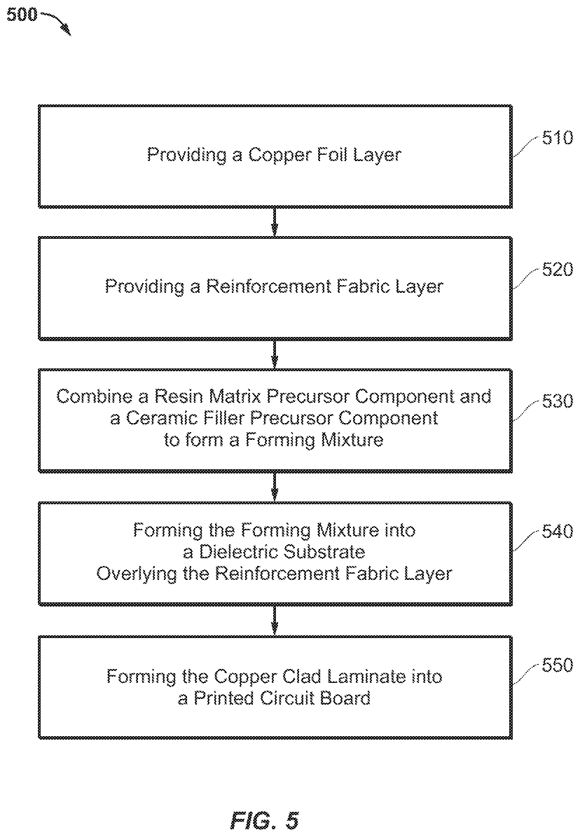

Referring next to a method of forming a printed circuit board, FIG. 5 includes a diagram showing a forming method 500 for forming a printed circuit board according to embodiments described herein. According to particular embodiments, the forming method 500 may include a first step 510 of providing a copper foil layer, a second step 520 of providing a reinforcement fabric layer overlying the copper foil layer, a third step 330 of combining a resin matrix precursor component and a ceramic filler precursor component to form a forming mixture, a fourth step 540 of forming the forming mixture into a dielectric substrate overlying the reinforcement fabric layer to form a copper-clad laminate, and a fifth step 550 of forming the copper-clad laminate into a printed circuit board.

It will be appreciated that all description, details and characteristics provided herein in reference to forming method 100 and/or forming method 300 may further apply to or describe correspond aspects of forming method 500.

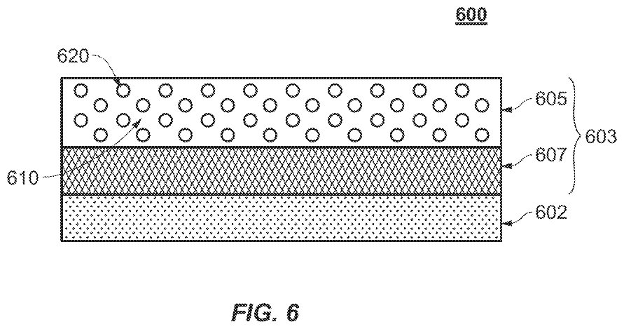

Referring now to embodiments of the printed circuit board formed according to forming method 500, FIG. 6 includes diagram of a printed circuit board 600. As shown in FIG. 6, the printed circuit board 600 may include a copper-clad laminate 601, which may include a copper foil layer 602, and a dielectric composite 603 overlying a surface of the copper foil layer 602. According to certain embodiments, the dielectric composite 603 may include a dielectric substrate 605 overlying a reinforcement fabric layer 607. According to still other embodiments, the dielectric substrate 605 may include a resin matrix component 610 and a ceramic filler component 620.

Again, it will be appreciated that all description provided herein in reference to dielectric substrate 201 (405) and/or copper-clad laminate 400 may further apply to correcting aspects of the printed circuit board 600, including all component of printed circuit board 600.

Many different aspects and embodiments are possible. Some of those aspects and embodiments are described herein. After reading this specification, skilled artisans will appreciate that those aspects and embodiments are only illustrative and do not limit the scope of the present invention. Embodiments may be in accordance with any one or more of the embodiments as listed below.

Embodiment 1. A dielectric composite comprising a dielectric substrate overlying a reinforcement fabric layer, wherein the dielectric substrate comprising: a resin matrix component; and ceramic filler component, wherein the ceramic filler component comprises a first filler material, and wherein a particle size distribution of the first filler material comprises: a D₁₀ of at least about 0.5 microns and not greater than about 1.6 microns, a D₅₀ of at least about 0.8 microns and not greater than about 2.7 microns, and a D₉₀ of at least about 1.5 microns and not greater than about 4.7 microns.

Embodiment 2. A dielectric composite comprising a dielectric substrate overlying a reinforcement fabric layer, wherein the dielectric substrate comprising: a resin matrix component; and a ceramic filler component, wherein the ceramic filler component comprises a first filler material, and wherein the first filler material further comprises a mean particle size of not greater than about 10 microns, and a particle size distribution span (PSDS) of not greater than about 5, where PSDS is equal to (D₉₀−D₁₀)/D₅₀, where D₉₀ is equal to a D₉₀ particle size distribution measurement of the first filler material, D₁₀ is equal to a D₁₀ particle size distribution measurement of the first filler material, and D₅₀ is equal to a D₅₀ particle size distribution measurement of the first filler material.

Embodiment 3. A dielectric composite comprising a dielectric substrate overlying a reinforcement fabric layer, wherein the dielectric substrate comprising: a resin matrix component; and a ceramic filler component, wherein the ceramic filler component comprises a first filler material, and wherein the first filler material further comprises a mean particle size of at not greater than about 10 microns, and an average surface area of not greater than about 8 m²/g.

Embodiment 4. The dielectric composite of any one of embodiments 1, 2, and 3, wherein the reinforcement fabric layer comprises a glass fabric material.

Embodiment 5. The dielectric composite of any one of embodiments 1, 2, and 3, wherein the reinforcement fabric layer comprises E-glass fabric, NE-glass fabric, S-glass fabric, L-glass fabric, D-glass fabric, quartz glass fabric, aromatic polyamide fabric (i.e. Kevlar fabric), polytetrafluoroethylene (PTFE) fabric, polyester fabric, liquid crystal polymer (LCP) fabric, or any combination thereof.

Embodiment 6. The dielectric composite of any one of embodiments 1, 2, and 3, wherein the reinforcement fabric layer comprises a woven fabric of fibrous material.

Embodiment 7. The dielectric composite of embodiment 6, wherein the fibrous material comprises E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof.

Embodiment 8. The dielectric composite of any one of embodiments 1, 2, and 3, wherein the reinforcement fabric layer comprises a non-woven fabric of fibrous material.

Embodiment 9. The dielectric composite of embodiment 8, wherein the fibrous material comprises E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof.

Embodiment 10. The dielectric composite of any one of embodiments 1, 2, and 3, wherein the reinforcement fabric layer has a thickness of at least about 4 microns.

Embodiment 11. The dielectric composite of any one of embodiments 1, 2, and 3, wherein the reinforcement fabric layer has a thickness of not greater than about 1 mm.

Embodiment 12. The dielectric composite of any one of embodiments 1, 2, and 3, wherein the dielectric composite further comprises an adhesive layer between the reinforcement fabric and the dielectric substrate.

Embodiment 13. The dielectric composite of embodiment 12, wherein the adhesive layer comprises PFA, FEP or any combination thereof.

Embodiment 14. The dielectric composite of embodiment 12, wherein the adhesive layer has a thickness of at least about 0.1 microns.

Embodiment 15. The dielectric composite of embodiment 12, wherein the adhesive layer has a thickness of not greater than about 25 microns.

Embodiment 16. The dielectric composite of any one of embodiments 1, 2, and 3, wherein the dielectric composite has a tensile modulus of at least about 200 MPA.

Embodiment 17. The dielectric composite of any one of embodiments 1, 2, and 3, wherein the dielectric composite has a tensile modulus of not greater than about 100000 MPa.

Embodiment 18. The dielectric composite of any one of embodiments 1, 2, and 3, wherein the dielectric composite has a storage modulus at room temperature of at least about 1200 MPa.

Embodiment 19. The dielectric composite of any one of embodiments 1, 2, and 3, wherein the dielectric composite has a storage modulus at room temperature of not greater than about 100000 MPa.

Embodiment 20. The dielectric composite of any one of embodiments 1, 2, and 3, wherein the dielectric composite has a storage modulus at 70° C. of at least about 600 MPa.

Embodiment 21. The dielectric composite of any one of embodiments 1, 2, and 3, wherein the dielectric composite has a storage modulus at 70° C. of not greater than about 100000 MPa.

Embodiment 22. The dielectric composite of any one of embodiments 1, 2, and 3, wherein the dielectric composite has a yield point of at least about 2 MPa.

Embodiment 23. The dielectric composite of any one of embodiments 1, 2, and 3, wherein the dielectric composite has a yield point of not greater than about 400 MPa.

Embodiment 24. The dielectric substrate of any one of embodiments 2 and 3, wherein a particle size distribution of the first filler material comprises a D₁₀ of at least about 0.5 microns and not greater than about 1.6 microns.

Embodiment 25. The dielectric substrate of any one of embodiments 2 and 3, wherein a particle size distribution of the first filler material comprises a D₅₀ of at least about 0.8 microns and not greater than about 2.7 microns.

Embodiment 26. The dielectric substrate of any one of embodiments 2 and 3, wherein a particle size distribution of the first filler material comprises a D₉₀ of at least about 1.5 microns and not greater than about 4.7 microns.

Embodiment 27. The dielectric substrate of embodiment 1, wherein the first filler material further comprises a mean particle size of at not greater than about 10 microns.

Embodiment 28. The dielectric substrate of any one of embodiments 2, 3, and 27, wherein the first filler material comprises a mean particle size of not greater than about 10 microns or not greater than about 9 microns or not greater than about 8 microns or not greater than about 7 microns or not greater than about 6 microns or not greater than about 5 microns or not greater than about 4 microns or not greater than about 3 microns or not greater than about 2 microns.

Embodiment 29. The dielectric substrate of any one of embodiments 1 and 3, wherein the first filler material comprises a particle size distribution span (PSDS) of not greater than about 5, where PSDS is equal to (D₉₀−D₁₀)/D₅₀, where D₉₀ is equal to a D₉₀ particle size distribution measurement of the first filler material, D₁₀ is equal to a D₁₀ particle size distribution measurement of the first filler material, and D₅₀ is equal to a D₅₀ particle size distribution measurement of the first filler material.

Embodiment 30. The dielectric substrate of any one of embodiments 1 and 2, wherein the first filler material further comprises an average surface area of not greater than about 8 m²/g.

Embodiment 31. The dielectric substrate of any one of embodiments 1, 2, and 3, wherein the first filler material comprises a silica-based compound.

Embodiment 32. The dielectric substrate of any one of embodiments 1, 2, and 3, wherein the first filler material comprises silica.

Embodiment 33. The dielectric substrate of any one of embodiments 1, 2, and 3, wherein the resin matrix comprises a perfluoropolymer.

Embodiment 34. The dielectric substrate of embodiment 33, wherein the perfluoropolymer comprises a copolymer of tetrafluoroethylene (TFE); a copolymer of hexafluoropropylene (HFP); a terpolymer of tetrafluoroethylene (TFE); or any combination thereof.

Embodiment 35. The dielectric substrate of embodiment 33, wherein the perfluoropolymer comprises polytetrafluoroethylene (PTFE), perfluoroalkoxy polymer resin (PFA), fluorinated ethylene propylene (FEP), or any combination thereof.

Embodiment 36. The dielectric substrate of embodiment 33, wherein the perfluoropolymer consists of polytetrafluoroethylene (PTFE), perfluoroalkoxy polymer resin (PFA), fluorinated ethylene propylene (FEP), or any combination thereof.

Embodiment 37. The dielectric substrate of any one of embodiments 1, 2, and 3, wherein the content of the resin matrix component is at least about 45 vol. % for a total volume of the dielectric substrate.

Embodiment 38. The dielectric substrate of any one of embodiments 1, 2, and 3, wherein the content of the resin matrix component is not greater than about 63 vol. % for a total volume of the dielectric substrate.

Embodiment 39. The dielectric substrate of embodiment 33, wherein the content of the perfluoropolymer is at least about 45 vol. % for a total volume of the dielectric substrate.

Embodiment 40. The dielectric substrate of embodiment 33, wherein the content of the perfluoropolymer is not greater than about 63 vol. % for a total volume of the dielectric substrate.

Embodiment 41. The dielectric substrate of any one of embodiments 1, 2, and 3, wherein the content of the ceramic filler component is at least about 45 vol. % for a total volume of the dielectric substrate.

Embodiment 42. The dielectric substrate of any one of embodiments 1, 2, and 3, wherein the content of the ceramic filler component is not greater than about 57 vol. % for a total volume of the dielectric substrate.

Embodiment 43. The dielectric substrate of any one of embodiments 1, 2, and 3, wherein the content of the first filler material is at least about 80 vol. % for a total volume of the ceramic filler component.

Embodiment 44. The dielectric substrate of any one of embodiments 1, 2, and 3, wherein the content of the first filler material is not greater than about 100 vol. % for a total volume of the ceramic filler component.

Embodiment 45. The dielectric substrate of any one of embodiments 1, 2, and 3, wherein the ceramic filler component further comprises a second filler material.

Embodiment 46. The dielectric substrate of embodiment 45, wherein the second filler material comprises a high dielectric constant ceramic material.

Embodiment 47. The dielectric substrate of embodiment 46, wherein the high dielectric constant ceramic material has a dielectric constant of at least about 14.

Embodiment 48. The dielectric substrate of embodiment 46, wherein the ceramic filler component further comprises TiO₂, SrTiO₃, ZrTi₂O₆, MgTiO₃, CaTiO₃, BaTiO₄ or any combination thereof.

Embodiment 49. The dielectric substrate of embodiment 45, wherein the content of the second filler material is at least about 1 vol. % for a total volume of the ceramic filler component.

Embodiment 50. The dielectric substrate of embodiment 45, wherein the content of the second filler material is not greater than about 20 vol. % for a total volume of the ceramic filler component.

Embodiment 51. The dielectric substrate of any one of embodiments 1, 2, and 3, wherein the ceramic filler component is at least about 97% amorphous.

Embodiment 52. The dielectric substrate of any one of embodiments 1, 2, and 3, wherein the dielectric substrate comprises a porosity of not greater than about 10 vol. %.

Embodiment 53. The dielectric substrate of any one of embodiments 1, 2, and 3, wherein the dielectric substrate comprises an average thickness of at least about 10 microns.

Embodiment 54. The dielectric substrate of any one of embodiments 1, 2, and 3, wherein the dielectric substrate comprises an average thickness of not greater than about 2000 microns.

Embodiment 55. The dielectric substrate of any one of embodiments 1, 2, and 3, wherein the dielectric substrate comprises a dissipation factor (5 GHz, 20% RH) of not greater than about 0.005.

Embodiment 56. The dielectric substrate of any one of embodiments 1, 2, and 3, wherein the dielectric substrate comprises a dissipation factor (5 GHz, 20% RH) of not greater than about 0.0014.

Embodiment 57. The dielectric substrate of any one of embodiments 1, 2, and 3, wherein the dielectric substrate comprises a coefficient of thermal expansion in the X axis, Y axis or Z axis of not greater than about 80 ppm/° C.

Embodiment 58. The dielectric substrate of any one of embodiments 1, 2, and 3, wherein the dielectric substrate comprises a moisture absorption of not greater than about 0.05%.

Embodiment 59. A copper-clad laminate comprising: a copper foil layer, and a dielectric composite overlying the copper foil layer, wherein the dielectric composite comprises a dielectric substrate overlying a reinforcement fabric layer, wherein the dielectric substrate comprises: a resin matrix component; and a ceramic filler component, wherein the ceramic filler component comprises a first filler material, and wherein a particle size distribution of the first filler material comprises: a D₁₀ of at least about 0.5 microns and not greater than about 1.6 microns, a D₅₀ of at least about 0.8 microns and not greater than about 2.7 microns, and a D₉₀ of at least about 1.5 microns and not greater than about 4.7 microns.

Embodiment 60. A copper-clad laminate comprising: a copper foil layer, and a dielectric composite overlying the copper foil layer, wherein the dielectric composite comprises a dielectric substrate overlying a reinforcement fabric layer, wherein the dielectric substrate comprises: a resin matrix component; and a ceramic filler component, wherein the ceramic filler component comprises a first filler material, wherein the first filler material further comprises a mean particle size of at not greater than about 10 microns, and a particle size distribution span (PSDS) of not greater than about 5, where PSDS is equal to (D₉₀−D₁₀)/D₅₀, where D₉₀ is equal to a D₉₀ particle size distribution measurement of the first filler material, D₁₀ is equal to a D₁₀ particle size distribution measurement of the first filler material, and D₅₀ is equal to a D₅₀ particle size distribution measurement of the first filler material.

Embodiment 61. A copper-clad laminate comprising: a copper foil layer, and a dielectric composite overlying the copper foil layer, wherein the dielectric composite comprises a dielectric substrate overlying a reinforcement fabric layer, wherein the dielectric substrate comprises: a resin matrix component; and a ceramic filler component, wherein the ceramic filler component comprises a first filler material, and wherein the first filler material further comprises a mean particle size of at not greater than about 10 microns, and an average surface area of not greater than about 8 m²/g.

Embodiment 62. The copper-clad laminate of any one of embodiments 59, 60, and 61, wherein the reinforcement fabric layer comprises a glass fabric material.

Embodiment 63. The copper-clad laminate of any one of embodiments 59, 60, and 61, wherein the reinforcement fabric layer comprises E-glass fabric, NE-glass fabric, S-glass fabric, L-glass fabric, D-glass fabric, quartz glass fabric, aromatic polyamide fabric (i.e. Kevlar fabric), polytetrafluoroethylene (PTFE) fabric, polyester fabric, liquid crystal polymer (LCP) fabric, or any combination thereof.

Embodiment 64. The copper-clad laminate of any one of embodiments 59, 60, and 61, wherein the reinforcement fabric layer comprises a woven fabric of fibrous material.

Embodiment 65. The copper-clad laminate of embodiment 64, wherein the fibrous material comprises E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof.

Embodiment 66. The copper-clad laminate of any one of embodiments 59, 60, and 61, wherein the reinforcement fabric layer comprises a non-woven fabric of fibrous material.

Embodiment 67. The copper-clad laminate of embodiment 66, wherein the fibrous material comprises E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof.

Embodiment 68. The copper-clad laminate of any one of embodiments 59, 60, and 61, wherein the reinforcement fabric layer has a thickness of at least about 4 microns.

Embodiment 69. The copper-clad laminate of any one of embodiments 59, 60, and 61, wherein the reinforcement fabric layer has a thickness of not greater than about 1 mm.

Embodiment 70. The copper-clad laminate of any one of embodiments 59, 60, and 61, wherein the dielectric composite further comprises an adhesive layer between the reinforcement fabric and the dielectric substrate.

Embodiment 71. The copper-clad laminate of embodiment 70, wherein the adhesive layer comprises PFA, FEP or any combination thereof.

Embodiment 72. The copper-clad laminate of embodiment 70, wherein the adhesive layer has a thickness of at least about 0.1 microns.

Embodiment 73. The copper-clad laminate of embodiment 70, wherein the adhesive layer has a thickness of not greater than about 25 microns.

Embodiment 74. The copper-clad laminate of any one of embodiments 59, 60, and 61, wherein the dielectric composite has a tensile modulus of at least about 200 MPa.

Embodiment 75. The copper-clad laminate of any one of embodiments 59, 60, and 61, wherein the dielectric composite has a tensile modulus of not greater than about 100000 MPa.

Embodiment 76. The copper-clad laminate of any one of embodiments 59, 60, and 61, wherein the dielectric composite has storage modulus at room temperature of at least about 1200 MPa.

Embodiment 77. The copper-clad laminate of any one of embodiments 59, 60, and 61, wherein the dielectric composite has a storage modulus at room temperature of not greater than about 100000 MPa.

Embodiment 78. The copper-clad laminate of any one of embodiments 59, 60, and 61, wherein the dielectric composite has a storage modulus at 70° C. of at least about 600 MPa.

Embodiment 79. The copper-clad laminate of any one of embodiments 59, 60, and 61, wherein the dielectric composite has a storage modulus at 70° C. of not greater than about 100000 MPa.

Embodiment 80. The copper-clad laminate of any one of embodiments 59, 60, and 61, wherein the dielectric composite has a yield point of at least about 2 MPa.

Embodiment 81. The copper-clad laminate of any one of embodiments 59, 60, and 61, wherein the dielectric composite has a yield point of not greater than about 400 MPa.

Embodiment 82. The copper-clad laminate of any one of embodiments 60 and 61, wherein a particle size distribution of the first filler material comprises a D₁₀ of at least about 0.5 microns and not greater than about 1.6 microns.

Embodiment 83. The copper-clad laminate of any one of embodiments 60 and 61, wherein a particle size distribution of the first filler material comprises a D₅₀ of at least about 0.8 microns and not greater than about 2.7 microns.

Embodiment 84. The copper-clad laminate of any one of embodiments 60 and 61, wherein a particle size distribution of the first filler material comprises a D₉₀ of at least about 1.5 microns and not greater than about 4.7 microns.

Embodiment 85. The copper-clad laminate of embodiment 59, wherein the first filler material further comprises a mean particle size of at not greater than about 10 microns.

Embodiment 86. The copper-clad laminate of any one of embodiments 59, 60, and 61, wherein the first filler material comprises a mean particle size of not greater than about 10 microns.

Embodiment 87. The copper-clad laminate of any one of embodiments 59 and 61, wherein the first filler material comprises a particle size distribution span (PSDS) of not greater than about 5, where PSDS is equal to (D₉₀−D₁₀)/D₅₀, where D₉₀ is equal to a D₉₀ particle size distribution measurement of the first filler material, D₁₀ is equal to a D₁₀ particle size distribution measurement of the first filler material, and D₅₀ is equal to a D₅₀ particle size distribution measurement of the first filler material.

Embodiment 88. The copper-clad laminate of any one of embodiments 59 and 60, wherein the first filler material further comprises an average surface area of not greater than about 8 m²/g.

Embodiment 89. The copper-clad laminate of any one of embodiments 59, 60, and 61, wherein the first filler material comprises a silica-based compound.

Embodiment 90. The copper-clad laminate of any one of embodiments 59, 60, and 61, wherein the first filler material comprises silica.

Embodiment 91. The copper-clad laminate of any one of embodiments 59, 60, and 61, wherein the resin matrix comprises a perfluoropolymer.

Embodiment 92. The copper-clad laminate of embodiment 91, wherein the perfluoropolymer comprises a copolymer of tetrafluoroethylene (TFE); a copolymer of hexafluoropropylene (HFP); a terpolymer of tetrafluoroethylene (TFE); or any combination thereof.

Embodiment 93. The copper-clad laminate of embodiment 91, wherein the perfluoropolymer comprises polytetrafluoroethylene (PTFE), perfluoroalkoxy polymer resin (PFA), fluorinated ethylene propylene (FEP), or any combination thereof.

Embodiment 94. The copper-clad laminate of embodiment 91, wherein the perfluoropolymer consists of polytetrafluoroethylene (PTFE), perfluoroalkoxy polymer resin (PFA), fluorinated ethylene propylene (FEP), or any combination thereof.

Embodiment 95. The copper-clad laminate of any one of embodiments 59, 60, and 61, wherein the content of the resin matrix component is at least about 45 vol. % for a total volume of the dielectric substrate.

Embodiment 96. The copper-clad laminate of any one of embodiments 59, 60, and 61, wherein the content of the resin matrix component is not greater than about 63 vol. % for a total volume of the dielectric substrate.

Embodiment 97. The copper-clad laminate of embodiment 91, wherein the content of the perfluoropolymer is at least about 45 vol. % for a total volume of the dielectric substrate.

Embodiment 98. The copper-clad laminate of embodiment 91, wherein the content of the perfluoropolymer is not greater than about 63 vol. % for a total volume of the dielectric substrate.

Embodiment 99. The copper-clad laminate of any one of embodiments 59, 60, and 61, wherein the content of the ceramic filler component is at least about 45 vol. % for a total volume of the dielectric substrate.

Embodiment 100. The copper-clad laminate of any one of embodiments 59, 60, and 61, wherein the content of the ceramic filler component is not greater than about 57 vol. % for a total volume of the dielectric substrate.

Embodiment 101. The copper-clad laminate of any one of embodiments 59, 60, and 61, wherein the content of the first filler material is at least about 80 vol. % for a total volume of the ceramic filler component.

Embodiment 102. The copper-clad laminate of any one of embodiments 59, 60, and 61, wherein the content of the first filler material is not greater than about 100 vol. % for a total volume of the ceramic filler component.

Embodiment 103. The copper-clad laminate of any one of embodiments 59, 60, and 61, wherein the ceramic filler component further comprises a second filler material.

Embodiment 104. The copper-clad laminate of embodiment 103, wherein the second filler material comprises a high dielectric constant ceramic material.

Embodiment 105. The copper-clad laminate of embodiment 104, wherein the high dielectric constant ceramic material has a dielectric constant of at least about 14.

Embodiment 106. The copper-clad laminate of embodiment 104, wherein the ceramic filler component further comprises TiO₂, SrTiO₃, ZrTi₂O₆, MgTiO₃, CaTiO₃, BaTiO₄ or any combination thereof.

Embodiment 107. The copper-clad laminate of embodiment 103, wherein the content of the second filler material is at least about 1 vol. % for a total volume of the ceramic filler component.

Embodiment 108. The copper-clad laminate of embodiment 103, wherein the content of the second filler material is not greater than about 20 vol. % for a total volume of the ceramic filler component.

Embodiment 109. The copper-clad laminate of any one of embodiments 59, 60, and 61, wherein the ceramic filler component is at least about 97% amorphous.

Embodiment 110. The copper-clad laminate of any one of embodiments 59, 60, and 61, wherein the dielectric substrate comprises a porosity of not greater than about 10 vol. %.

Embodiment 111. The copper-clad laminate of any one of embodiments 59, 60, and 61, wherein the dielectric substrate comprises an average thickness of at least about 10 microns.

Embodiment 112. The copper-clad laminate of any one of embodiments 59, 60, and 61, wherein the dielectric substrate comprises an average thickness of not greater than about 2000 microns.

Embodiment 113. The copper-clad laminate of any one of embodiments 59, 60, and 61, wherein the dielectric substrate comprises a dissipation factor (5 GHz, 20% RH) of not greater than about 0.005.

Embodiment 114. The copper-clad laminate of any one of embodiments 59, 60, and 61, wherein the dielectric substrate comprises a dissipation factor (5 GHz, 20% RH) of not greater than about 0.0014.

Embodiment 115. The copper-clad laminate of any one of embodiments 59, 60, and 61, wherein the dielectric substrate comprises a coefficient of thermal expansion in the X axis, Y axis or Z axis of not greater than about 80 ppm/° C.

Embodiment 116. The copper-clad laminate of any one of embodiments 59, 60, and 61, wherein the dielectric substrate comprises a moisture absorption of not greater than about 0.05%.

Embodiment 117. The copper-clad laminate of any one of embodiments 59, 60, and 61, wherein the copper-clad laminate comprises a porosity of not greater than about 10 vol. %.

Embodiment 118. The copper-clad laminate of any one of embodiments 59, 60, and 61, wherein the copper-clad laminate comprises a peel strength between the copper foil layer and the dielectric substrate of at least about 6 lb/in.

Embodiment 119. A printed circuit board comprising a copper-clad laminate, wherein the copper-clad laminate comprises: a copper foil layer, and a dielectric composite overlying the copper foil layer, wherein the dielectric composite comprises a dielectric substrate overlying a reinforcement fabric layer, wherein the dielectric substrate comprises: a resin matrix component; and a ceramic filler component, wherein the ceramic filler component comprises a first filler material, and wherein a particle size distribution of the first filler material comprises: a D₁₀ of at least about 0.5 microns and not greater than about 1.6 microns, a D₅₀ of at least about 0.8 microns and not greater than about 2.7 microns, and a D₉₀ of at least about 1.5 microns and not greater than about 4.7 microns.

Embodiment 120. A printed circuit board comprising a copper-clad laminate, wherein the copper-clad laminate comprises: a copper foil layer, and a dielectric composite overlying the copper foil layer, wherein the dielectric composite comprises a dielectric substrate overlying a reinforcement fabric layer, wherein the dielectric substrate comprises: a resin matrix component; and a ceramic filler component, wherein the ceramic filler component comprises a first filler material, wherein the first filler material further comprises a mean particle size of at not greater than about 10 microns, and a particle size distribution span (PSDS) of not greater than about 5, where PSDS is equal to (D₉₀−D₁₀)/D₅₀, where D₉₀ is equal to a D₉₀ particle size distribution measurement of the first filler material, D₁₀ is equal to a D₁₀ particle size distribution measurement of the first filler material, and D₅₀ is equal to a D₅₀ particle size distribution measurement of the first filler material.

Embodiment 121. A printed circuit board comprising a copper-clad laminate, wherein the copper-clad laminate comprises: a copper foil layer, and a dielectric composite overlying the copper foil layer, wherein the dielectric composite comprises a dielectric substrate overlying a reinforcement fabric layer, wherein the dielectric substrate comprises: a resin matrix component; and a ceramic filler component, wherein the ceramic filler component comprises a first filler material, and wherein the first filler material further comprises a mean particle size of at not greater than about 10 microns, and an average surface area of not greater than about 8 m²/g.

Embodiment 122. The printed circuit board of any one of embodiments 119, 120, and 121, wherein the reinforcement fabric layer comprises a glass fabric material.

Embodiment 123. The printed circuit board of any one of embodiments 119, 120, and 121, wherein the reinforcement fabric layer comprises E-glass fabric, NE-glass fabric, S-glass fabric, L-glass fabric, D-glass fabric, quartz glass fabric, aromatic polyamide fabric (i.e. Kevlar fabric), polytetrafluoroethylene (PTFE) fabric, polyester fabric, liquid crystal polymer (LCP) fabric, or any combination thereof.

Embodiment 124. The printed circuit board of any one of embodiments 119, 120, and 121, wherein the reinforcement fabric layer comprises a woven fabric of fibrous material.

Embodiment 125. The printed circuit board of embodiment 124, wherein the fibrous material comprises E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof.

Embodiment 126. The printed circuit board of any one of embodiments 119, 120, and 121, wherein the reinforcement fabric layer comprises a non-woven fabric of fibrous material.

Embodiment 127. The printed circuit board of embodiment 126, wherein the fibrous material comprises E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof.

Embodiment 128. The printed circuit board of any one of embodiments 119, 120, and 121, wherein the reinforcement fabric layer has a thickness of at least about 4 microns.

Embodiment 129. The printed circuit board of any one of embodiments 119, 120, and 121, wherein the reinforcement fabric layer has a thickness of not greater than about 1 mm.

Embodiment 130. The printed circuit board of any one of embodiments 119, 120, and 121, wherein the dielectric composite further comprises an adhesive layer between the reinforcement fabric and the dielectric substrate.

Embodiment 131. The printed circuit board of embodiment 130, wherein the adhesive layer comprises PFA, FEP or any combination thereof.

Embodiment 132. The printed circuit board of embodiment 130, wherein the adhesive layer has a thickness of at least about 0.1 microns.

Embodiment 133. The printed circuit board of embodiment 130, wherein the adhesive layer has a thickness of not greater than about 25 microns.

Embodiment 134. The printed circuit board of any one of embodiments 119, 120, and 121, wherein the dielectric composite has a tensile modulus of at least about 200 MPa.

Embodiment 135. The printed circuit board of any one of embodiments 119, 120, and 121, wherein the dielectric composite has a tensile modulus of not greater than about 100000 MPa.

Embodiment 136. The printed circuit board of any one of embodiments 119, 120, and 121, wherein the dielectric composite has a storage modulus at room temperature of at least about 1200 MPa.

Embodiment 137. The printed circuit board of any one of embodiments 119, 120, and 121, wherein the dielectric composite has a storage modulus at room temperature of not greater than about 100000 MPa.

Embodiment 138. The printed circuit board of any one of embodiments 119, 120, and 121, wherein the dielectric composite has a storage modulus at 70° C. of at least about 600 MPa.

Embodiment 139. The printed circuit board of any one of embodiments 119, 120, and 121, wherein the dielectric composite has a storage modulus at 70° C. of not greater than about 100000 MPa.

Embodiment 140. The printed circuit board of any one of embodiments 119, 120, and 121, wherein the dielectric composite has a yield point of at least about 2 MPa.

Embodiment 141. The printed circuit board of any one of embodiments 119, 120, and 121, wherein the dielectric composite has a yield point of not greater than about 400 MPa.

Embodiment 142. The printed circuit board of any one of embodiments 120 and 121, wherein a particle size distribution of the first filler material comprises a D₁₀ of at least about 0.5 microns and not greater than about 1.6 microns.

Embodiment 143. The printed circuit board of any one of embodiments 120 and 121, wherein a particle size distribution of the first filler material comprises a D₅₀ of at least about 0.8 microns and not greater than about 2.7 microns.

Embodiment 144. The printed circuit board of any one of embodiments 120 and 121, wherein a particle size distribution of the first filler material comprises a D₉₀ of at least about 1.5 microns and not greater than about 4.7 microns.

Embodiment 145. The printed circuit board of embodiment 119, wherein the first filler material further comprises a mean particle size of at not greater than about 10 microns.

Embodiment 146. The printed circuit board of any one of embodiments 119, 120, and 121, wherein the first filler material comprises a mean particle size of not greater than about 10 microns.

Embodiment 147. The printed circuit board of any one of embodiments 119 and 121, wherein the first filler material comprises a particle size distribution span (PSDS) of not greater than about 5, where PSDS is equal to (D₉₀−D₁₀)/D₅₀, where D₉₀ is equal to a D₉₀ particle size distribution measurement of the first filler material, D₁₀ is equal to a D₁₀ particle size distribution measurement of the first filler material, and D₅₀ is equal to a D₅₀ particle size distribution measurement of the first filler material.

Embodiment 148. The printed circuit board of any one of embodiments 119 and 120, wherein the first filler material further comprises an average surface area of not greater than about 8 m²/g.

Embodiment 149. The printed circuit board of any one of embodiments 119, 120, and 121, wherein the first filler material comprises a silica-based compound.

Embodiment 150. The printed circuit board of any one of embodiments 119, 120, and 121, wherein the first filler material comprises silica.

Embodiment 151. The printed circuit board of any one of embodiments 119, 120, and 121, wherein the resin matrix comprises a perfluoropolymer.

Embodiment 152. The printed circuit board of embodiment 151, wherein the perfluoropolymer comprises a copolymer of tetrafluoroethylene (TFE); a copolymer of hexafluoropropylene (HFP); a terpolymer of tetrafluoroethylene (TFE); or any combination thereof.

Embodiment 153. The printed circuit board of embodiment 151, wherein the perfluoropolymer comprises polytetrafluoroethylene (PTFE), perfluoroalkoxy polymer resin (PFA), fluorinated ethylene propylene (FEP), or any combination thereof.

Embodiment 154. The printed circuit board of embodiment 151, wherein the perfluoropolymer consists of polytetrafluoroethylene (PTFE), perfluoroalkoxy polymer resin (PFA), fluorinated ethylene propylene (FEP), or any combination thereof.

Embodiment 155. The printed circuit board of any one of embodiments 119, 120, and 121, wherein the content of the resin matrix component is at least about 45 vol. % for a total volume of the dielectric substrate.

Embodiment 156. The printed circuit board of any one of embodiments 119, 120, and 121, wherein the content of the resin matrix component is not greater than about 63 vol. % for a total volume of the dielectric substrate.

Embodiment 157. The printed circuit board of embodiment 151, wherein the content of the perfluoropolymer is at least about 45 vol. % for a total volume of the dielectric substrate.

Embodiment 158. The printed circuit board of embodiment 151, wherein the content of the perfluoropolymer is not greater than about 63 vol. % for a total volume of the dielectric substrate.

Embodiment 159. The printed circuit board of any one of embodiments 119, 120, and 121, wherein the content of the ceramic filler component is at least about 45 vol. % for a total volume of the dielectric substrate.

Embodiment 160. The printed circuit board of any one of embodiments 119, 120, and 121, wherein the content of the ceramic filler component is not greater than about 57 vol. % for a total volume of the dielectric substrate.

Embodiment 161. The printed circuit board of any one of embodiments 119, 120, and 121, wherein the content of the first filler material is at least about 80 vol. % for a total volume of the ceramic filler component.

Embodiment 162. The printed circuit board of any one of embodiments 119, 120, and 121, wherein the content of the first filler material is not greater than about 100 vol. % for a total volume of the ceramic filler component.

Embodiment 163. The printed circuit board of any one of embodiments 119, 120, and 121, wherein the ceramic filler component further comprises a second filler material.

Embodiment 164. The printed circuit board of embodiment 163, wherein the second filler material comprises a high dielectric constant ceramic material.

Embodiment 165. The printed circuit board of embodiment 164, wherein the high dielectric constant ceramic material has a dielectric constant of at least about 14.

Embodiment 166. The printed circuit board of embodiment 164, wherein the ceramic filler component further comprises TiO₂, SrTiO₃, ZrTi₂O₆, MgTiO₃, CaTiO₃, BaTiO₄ or any combination thereof.

Embodiment 167. The printed circuit board of embodiment 163, wherein the content of the second filler material is at least about 1 vol. % for a total volume of the ceramic filler component.

Embodiment 168. The printed circuit board of embodiment 163, wherein the content of the second filler material is not greater than about 20 vol. % for a total volume of the ceramic filler component.

Embodiment 169. The printed circuit board of any one of embodiments 119, 120, and 121, wherein the ceramic filler component is at least about 97% amorphous.

Embodiment 170. The printed circuit board of any one of embodiments 119, 120, and 121, wherein the dielectric substrate comprises a porosity of not greater than about 10 vol. %.

Embodiment 171. The printed circuit board of any one of embodiments 119, 120, and 121, wherein the dielectric substrate comprises an average thickness of at least about 10 microns.

Embodiment 172. The printed circuit board of any one of embodiments 119, 120, and 121, wherein the dielectric substrate comprises an average thickness of not greater than about 2000 microns.

Embodiment 173. The printed circuit board of any one of embodiments 119, 120, and 121, wherein the dielectric substrate comprises a dissipation factor (5 GHz, 20% RH) of not greater than about 0.005.

Embodiment 174. The printed circuit board of any one of embodiments 119, 120, and 121, wherein the dielectric substrate comprises a dissipation factor (5 GHz, 20% RH) of not greater than about 0.0014.

Embodiment 175. The printed circuit board of any one of embodiments 119, 120, and 121, wherein the dielectric substrate comprises a coefficient of thermal expansion in the X axis, Y axis or Z axis of not greater than about 80 ppm/° C.

Embodiment 176. The printed circuit board of any one of embodiments 119, 120, and 121, wherein the dielectric substrate comprises a moisture absorption of not greater than about 0.05%.

Embodiment 177. The printed circuit board of any one of embodiments 119, 120, and 121, wherein the copper-clad laminate comprises a porosity of not greater than about 10 vol. %.

Embodiment 178. The printed circuit board of any one of embodiments 119, 120, and 121, wherein the copper-clad laminate comprises a peel strength between the copper foil layer and the printed circuit board of at least about 6 lb/in.

Embodiment 179. A method of forming a dielectric composite, wherein the method comprises: providing a reinforcement fabric layer; combining a resin matrix precursor component and a ceramic filler precursor component to form a forming mixture; and forming the forming mixture into a dielectric substrate overlying the reinforcement fabric layer, wherein the ceramic filler precursor component comprises a first filler precursor material, and wherein a particle size distribution of the first filler precursor material comprises: a D₁₀ of at least about 0.5 microns and not greater than about 1.6 microns, a D₅₀ of at least about 0.8 microns and not greater than about 2.7 microns, and a D₉₀ of at least about 1.5 microns and not greater than about 4.7 microns.

Embodiment 180. A method of forming a dielectric composite, wherein the method comprises: providing a reinforcement fabric layer; combining a resin matrix precursor component and a ceramic filler precursor component to form a forming mixture; and forming the forming mixture into a dielectric substrate overlying the reinforcement fabric layer, wherein the ceramic filler precursor component comprises a first filler precursor material, wherein the first filler precursor material further comprises a mean particle size of at not greater than about 10 microns, and a particle size distribution span (PSDS) of not greater than about 5, where PSDS is equal to (D₉₀−D₁₀)/D₅₀, where D₉₀ is equal to a D₉₀ particle size distribution measurement of the first filler precursor material, D₁₀ is equal to a D₁₀ particle size distribution measurement of the first filler precursor material, and D₅₀ is equal to a D₅₀ particle size distribution measurement of the first filler precursor material.

Embodiment 181. A method of forming a dielectric composite, wherein the method comprises: providing a reinforcement fabric layer; combining a resin matrix precursor component and a ceramic filler precursor component to form a forming mixture; and forming the forming mixture into a dielectric substrate overlying the reinforcement fabric layer, wherein the ceramic filler precursor component comprises a first filler precursor material, and wherein the first filler precursor material further comprises a mean particle size of at not greater than about 10 microns, and an average surface area of not greater than about 8 m²/g.

Embodiment 182. A method of forming a copper-clad laminate, wherein the method comprises: providing a copper foil layer, providing a reinforcement fabric layer overlying the copper foil layer; combining a resin matrix precursor component and a ceramic filler precursor component to form a forming mixture, forming the forming mixture into a dielectric substrate overlying the reinforcement fabric layer, wherein the ceramic filler precursor component comprises a first filler precursor material, and wherein a particle size distribution of the first filler precursor material comprises: a D₁₀ of at least about 0.5 microns and not greater than about 1.6 microns, a D₅₀ of at least about 0.8 microns and not greater than about 2.7 microns, and a D₉₀ of at least about 1.5 microns and not greater than about 4.7 microns.

Embodiment 183. A method of forming a copper-clad laminate, wherein the method comprises: providing a copper foil layer, providing a reinforcement fabric layer overlying the copper foil layer; combining a resin matrix precursor component and a ceramic filler precursor component to form a forming mixture, forming the forming mixture into a dielectric substrate overlying the reinforcement fabric layer, wherein the ceramic filler precursor component comprises a first filler precursor material, wherein the first filler precursor material further comprises a mean particle size of at not greater than about 10 microns, and a particle size distribution span (PSDS) of not greater than about 5, where PSDS is equal to (D₉₀−D₁₀)/D₅₀, where D₉₀ is equal to a D₉₀ particle size distribution measurement of the first filler precursor material, D₁₀ is equal to a D₁₀ particle size distribution measurement of the first filler precursor material, and D₅₀ is equal to a D₅₀ particle size distribution measurement of the first filler precursor material.

Embodiment 184. A method of forming a copper-clad laminate, wherein the method comprises: providing a copper foil layer, providing a reinforcement fabric layer overlying the copper foil layer; combining a resin matrix precursor component and a ceramic filler precursor component to form a forming mixture, forming the forming mixture into a dielectric substrate overlying the reinforcement fabric layer, wherein the ceramic filler precursor component comprises a first filler precursor material, and wherein the first filler precursor material further comprises a mean particle size of at not greater than about 10 microns, and an average surface area of not greater than about 8 m²/g.

Embodiment 185. A method of forming a printed circuit board, wherein the method comprises: providing a copper foil layer, providing a reinforcement fabric layer overlying the copper foil layer; combining a resin matrix precursor component and a ceramic filler precursor component to form a forming mixture, forming the forming mixture into a dielectric substrate overlying the reinforcement fabric layer, wherein the ceramic filler precursor component comprises a first filler precursor material, and wherein a particle size distribution of the first filler precursor material comprises: a D₁₀ of at least about 0.5 microns and not greater than about 1.6 microns, a D₅₀ of at least about 0.8 microns and not greater than about 2.7 microns, and a D₉₀ of at least about 1.5 microns and not greater than about 4.7 microns.

Embodiment 186. A method of forming a printed circuit board, wherein the method comprises: providing a copper foil layer, providing a reinforcement fabric layer overlying the copper foil layer; combining a resin matrix precursor component and a ceramic filler precursor component to form a forming mixture, forming the forming mixture into a dielectric substrate overlying the reinforcement fabric layer, wherein the ceramic filler precursor component comprises a first filler precursor material, wherein the first filler precursor material further comprises a mean particle size of at not greater than about 10 microns, and a particle size distribution span (PSDS) of not greater than about 5, where PSDS is equal to (D₉₀−D₁₀)/D₅₀, where D₉₀ is equal to a D₉₀ particle size distribution measurement of the first filler precursor material, D₁₀ is equal to a D₁₀ particle size distribution measurement of the first filler precursor material, and D₅₀ is equal to a D₅₀ particle size distribution measurement of the first filler precursor material.

Embodiment 187. A method of forming a printed circuit board, wherein the method comprises: providing a copper foil layer, providing a reinforcement fabric layer overlying the copper foil layer; combining a resin matrix precursor component and a ceramic filler precursor component to form a forming mixture, forming the forming mixture into a dielectric substrate overlying the reinforcement fabric layer, wherein the ceramic filler precursor component comprises a first filler precursor material, and wherein the first filler precursor material further comprises a mean particle size of at not greater than about 10 microns, and an average surface area of not greater than about 8 m²/g.

### EXAMPLES

The concepts described herein will be further described in the following Examples, which do not limit the scope of the invention described in the claims.

### Example 1

Sample dielectric substrates S1-S12 were configured and formed according to certain embodiments described herein.

Each sample dielectric substrate was formed using a cast film process where a fluoropolymer pre-treated polyimide carrier belt is passed through a dip pan containing an aqueous forming mixture (i.e., the combination of the resin matrix component and the ceramic filler component) at the base of the coating tower. The coated carrier belt then passes through a metering zone in which metering bars remove excess dispersion from the coated carrier belt. After the metering zone, the coated carrier belt passes into a drying zone maintained at a temperature between 82° C. and 121° C. to evaporate the water. The coated carrier belt with the dried film then passes through a bake zone maintained at a temperature between 315° C. and 343° C. Finally, the carrier belt passes through a fusing zone maintained at a temperature between 349° C. and 399° C. to sinter, i.e., coalesce, the resin matrix material. The coated carrier belt then passes through a cooling plenum from which it can be directed either to a subsequent dip pan to begin formation of a further layer of the film or to a stripping apparatus. When the desired film thickness is achieved, the films are stripped off of the carrier belt.

The resin matrix component for each sample dielectric substrates S1-S12 is polytetrafluoroethylene (PTFE). Further configuration and composition details of each dielectric substrate S1-S12 are summarized in Table 1 below.

TABLE 1
Sample Dielectric Substrate Configuration and Composition

| | | | Dielectric Substrate Composition | | | |
|---|---|---|---|---|---|---|
| | | | Ceramic Filler | Resin Matrix | First Filler | Second |
| | | | Component | Component | Material -Silica | Ceramic Filler |
| | Sample | Silica Based | (vol. % of | (vol. % of | Based Component | Material (TiO₂) |
| Sample | Thickness | Component | dielectric | dielectric | (vol. % of Ceramic | (vol. % of Ceramic |
| No. | (mil) | Type | substrate) | substrate) | Filler Component) | Filler Component) |
| S1 | 5 | A | 54.4 | 45.6 | 96.1 | 3.9 |
| S2 | 5 | A | 54.4 | 45.6 | 96.1 | 3.9 |
| S3 | 5 | A | 54.4 | 45.6 | 96.1 | 3.9 |
| S4 | 3 | A | 54.4 | 45.6 | 96.1 | 3.9 |
| S5 | 4 | A | 54.4 | 45.6 | 100.00 | 0.0 |
| S6 | 4 | A | 54.4 | 45.6 | 100.0 | 0.0 |
| S7 | 4 | A | 54.4 | 45.6 | 100.0 | 0.0 |
| S8 | 4 | A | 54.4 | 45.6 | 100.0 | 0.0 |
| S9 | 2 | A | 55.0 | 45.0 | 100.0 | 0.0 |
| S10 | 2 | B | 54.4 | 45.6 | 100.0 | 0.0 |
| S11 | 4 | A | 48.0 | 52.0 | 100.0 | 0.0 |
| S12 | 4 | A | 48.0 | 52.0 | 100.0 | 0.0 |

Characteristics, including particle size distribution measurements (i.e., D₁₀, D₅₀ & D₉₀), particle size distribution span, mean particle size, and BET surface area, of the silica-based component types used in the sample dielectric substrates S1-S12 are summarized in Table 2 below.

TABLE 2
Silica Based Component Characteristics

| | | | | | | BET |
|---|---|---|---|---|---|---|
| Silica Based | | | | PSDS | Mean | Surface |
| Component | D₁₀ | D₅₀ | D₉₀ | (D₉₀ − | Particle | Area |
| Type | (μm) | (μm) | (μm) | D₁₀)/D₅₀ | Size (μm) | (m²/g) |
| A | 1.3 | 2.3 | 3.9 | 1.13 | 2.3-3.0 | 2.2-2.5 |
| B | 0.5 | 1.1 | 1.6 | 1.0 | 1.0-1.9 | 6.1 |

Performance properties of each sample dielectric substrates S1-S12 are summarized in Table 3 below. The summarized performance properties include the permittivity of the sample dielectric substrate measured at 5 GHz (“Dk (5 GHz)”), the dissipation factor of the substrate measured at 5 GHz, 20% RH (“Df (5 GHz, 20% RH)”), the dissipation factor of the sample dielectric substrate measured at 5 GHz, 80% RH (“Df (5 GHz, 80% RH)”), and the coefficient of thermal expansion of the sample dielectric substrate (“CTE”).

TABLE 3
Performance Properties

| Sample | Dk | Df (5 GHz, | Df (5 GHz, | CTE |
|---|---|---|---|---|
| No. | (5 GHz) | 20% RH) | 80% RH) | (ppm/° C.) |
| S1 | 3.02 | 0.0005 | 0.0006 | 29 |
| S2 | 3.00 | 0.0005 | 0.0007 | 28 |
| S3 | 3.02 | 0.0005 | 0.0006 | 25 |
| S4 | 2.95 | 0.0004 | 0.0006 | 20 |
| S5 | 2.76 | 0.0004 | 0.0005 | 29 |
| S6 | 2.78 | 0.0004 | 0.0005 | 19 |
| S7 | 2.73 | 0.0005 | 0.0006 | 26 |
| S8 | 2.75 | 0.0004 | 0.0006 | 31 |
| S9 | 2.78 | 0.0005 | 0.0006 | 30 |
| S10 | 2.70 | 0.0007 | 0.0010 | 34 |
| S11 | 2.68 | 0.0005 | 0.0006 | 54 |
| S12 | 2.72 | 0.0004 | 0.0007 | 58 |

### Example 2

For purposes of comparison, comparative sample dielectric substrates CS1-CS10 were configured and formed.

Each comparative sample dielectric substrate was formed using a cast film process where a fluoropolymer pre-treated polyimide carrier belt is passed through a dip pan containing an aqueous forming mixture (i.e., the combination of the resin matrix component and the ceramic filler component) at the base of the coating tower. The coated carrier belt then passes through a metering zone in which metering bars remove excess dispersion from the coated carrier belt. After the metering zone, the coated carrier belt passes into a drying zone maintained at a temperature between 82° C. and 121° C. to evaporate the water. The coated carrier belt with the dried film then passes through a bake zone maintained at a temperature between 315° C. and 343° C. Finally, the carrier belt passes through a fusing zone maintained at a temperature between 349° C. and 399° C. to sinter, i.e., coalesce, the resin matrix material. The coated carrier belt then passes through a cooling plenum from which it can be directed either to a subsequent dip pan to begin formation of a further layer of the film or to a stripping apparatus. When the desired film thickness is achieved, the films are stripped off of the carrier belt.

The resin matrix component for each comparative sample dielectric substrates CS1-CS10 is polytetrafluoroethylene (PTFE). Further configuration and composition details of each dielectric substrate CS1-CS10 are summarized in Table 4 below.

TABLE 4
Comparative Sample Dielectric Substrate Configuration and Composition

| | | | Dielectric Substrate Composition | | | |
|---|---|---|---|---|---|---|
| | | | Ceramic Filler | Resin Matrix | First Filler | Second |
| | | | Component | Component | Material -Silica | Ceramic Filler |
| | Sample | Silica Based | (vol. % of | (vol. % of | Based Component | Material (TiO₂) |
| Sample | Thickness | Component | dielectric | dielectric | (vol. % of Ceramic | (vol. % of Ceramic |
| No. | (mil) | Type | substrate) | substrate) | Filler Component) | Filler Component) |
| CS1 | 5 | CA | 55.0 | 45.0 | 100.0 | 0.0 |
| CS2 | 5 | CB | 50.0 | 50.0 | 100.0 | 0.0 |
| CS3 | 5 | CA | 50.0 | 50.0 | 100.0 | 0.0 |
| CS4 | 5 | CC | 54.4 | 45.6 | 96.1 | 3.9 |
| CS5 | 5 | CA | 50.0 | 50.0 | 98.0 | 2.0 |
| CS6 | 5 | CA | 50.0 | 50.0 | 90.0 | 10.0 |
| CS7 | 5 | CA | 52.0 | 48.0 | 96.2 | 3.8 |
| CS8 | 5 | CA | 53.0 | 47.0 | 93.4 | 6.6 |
| CS9 | 5 | CA | 54.0 | 46.0 | 95.9 | 4.1 |

Characteristics, including particle size distribution measurements (i.e., D₁₀, D₅₀ & D₉₀), particle size distribution span, mean particle size, and BET surface area, of the silica-based component types used in the sample dielectric substrates CS1-CS9 are summarized in Table 2 below.

TABLE 5
Silica Based Component Characteristics

| | | | | | | BET |
|---|---|---|---|---|---|---|
| Silica Based | | | | PSDS | Mean | Surface |
| Component | D₁₀ | D₅₀ | D₉₀ | (D₉₀ − | Particle | Area |
| Type | (μm) | (μm) | (μm) | D₁₀)/D₅₀ | Size (μm) | (m²/g) |
| CA | 4.9 | 13.9 | 30.4 | 1.83 | 16.3 | 3.3 |
| CB | 4.1 | 7.3 | 12.6 | 1.16 | 7.9 | 4.6 |
| CC | 4.6 | 6.9 | 11.1 | 0.94 | 7.5 | 2.6 |

Performance properties of each sample dielectric substrates CS1-S9 are summarized in Table 6 below. The summarized performance properties include the permittivity of the sample dielectric substrate measured at 5 GHz (“Dk (5 GHz)”), the dissipation factor of the substrate measured at 5 GHz, 20% RH (“Df (5 GHz, 20% RH)”), the dissipation factor of the sample dielectric substrate measured at 5 GHz, 80% RH (“Df (5 GHz, 80% RH)”), and the coefficient of thermal expansion of the sample dielectric substrate (“CTE”).

TABLE 6
Performance Properties

| Sample | Dk | Df (5 GHz, | Df (5 GHz, | CTE |
|---|---|---|---|---|
| No. | (5 GHz) | 20% RH) | 80% RH) | (ppm/° C.) |
| CS1 | 2.55 | 0.0006 | 0.0009 | 25 |
| CS2 | 2.60 | 0.0008 | 0.0009 | 24 |
| CS3 | 2.53 | 0.0008 | 0.0018 | 31 |
| CS4 | 3.02 | 0.0005 | 0.0005 | 56 |
| CS5 | 2.64 | 0.0012 | 0.0026 | 30 |
| CS6 | 3.04 | 0.0017 | 0.0025 | 40 |
| CS7 | 2.71 | 0.0008 | 0.0013 | 36 |
| CS8 | 2.83 | 0.0015 | 0.0026 | 42 |
| CS9 | 2.82 | 0.0007 | 0.0014 | 31 |

### Example 3

Sample dielectric composites S13-S17 were configured and formed according to certain embodiments described herein. Each sample dielectric composite S13-S17 includes at least one dielectric substrate formed as described above in reference to sample dielectric substrate S8 and is overlying and/or underlying a reinforcement fabric.

Further configuration details of each dielectric composite S13-S17 are summarized in Table 7 below. For purposes of describing the structure configuration for each dielectric composite S13-S17, “B” represents the dielectric substrate, “R1” represents a reinforcement fabric having a warp count of 66, a fill count of 68, a yarn type of D900 1/0, a weight of 0.88 osy, and a thickness of 1.1 mil, “R2” represents a reinforcement fabric having a warp count of 54, a fill count of 54, a yarn type of D450 1/0, a weight of 1.41 osy, and a thickness of 1.7 mil, and “X” represents an adhesive layer.

TABLE 7
Sample Dielectric Composite Configuration and Composition

| | | Dielectric | Dielectric |
|---|---|---|---|
| Sample | | Substrate—“B” | Composite |
| No. | Configuration | Thickness (mil) | Thickness (mil) |
| S13 | B/X/R1/B/X/R1/X/B | 2 | 8 |
| S14 | B/R1/B | 4 | 8 |
| S15 | B/X/R2/X/B | 2 | 5 |
| S16 | B/X/R2/X/B | 3 | 7 |
| S17 | B/R2/B | 4 | 9 |

Performance properties of each sample dielectric substrates S13-S17 are summarized in Table 8 below. The summarized performance properties include the yield strength as measured according to IPC-TM-650 2-4-18.3, the tensile strength as measured according to IPC-TM-650 2-4-18.3, the storage modulus as measured according to IPC-TM-650 2-4-18.3, the permittivity measured at 5 GHz (“Dk (5 GHz)”), the dissipation factor of the substrate measured at 5 GHz, 20% RH (“Df (5 GHz, 20% RH)”), the dissipation factor of the sample dielectric substrate measured at 5 GHz, 80% RH (“Df (5 GHz, 80% RH)”), and the coefficient of thermal expansion of the sample dielectric substrate (“CTE”).

TABLE 8
Performance Properties

| | Yield | Tensile | Storage | Storage | | | | |
|---|---|---|---|---|---|---|---|---|
| | strength | modulus | modulus | modulus | | Df | Df | |
| Sample | at 22° C. | at 22° C. | at 22° C. | at 70° C. | Dk | (5 GHz, | (5 GHz, | CTE |
| No. | (MPa) | (MPa) | (MPa) | (MPa) | (5 GHz) | 20% RH) | 80% RH) | (ppm/° C.) |
| S13 | 52.8 | 8894 | 4442 | 3911 | 3.06 | 0.0019 | 0.0021 | 9 |
| S14 | 46.2 | 5746 | 4680 | 4170 | 2.87 | 0.0013 | 0.0016 | 13 |
| S15 | 25.6 | 8924 | 2780 | 2250 | 3.18 | 0.0025 | 0.0026 | — |
| S16 | 35.3 | 8824 | 4596 | 3730 | 3.02 | 0.0017 | 0.0018 | 10 |
| S17 | 23.8 | 8942 | 3310 | 2940 | 2.91 | 0.0015 | 0.0017 | 12 |

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A dielectric composite comprising a dielectric substrate overlying a reinforcement fabric layer, wherein the dielectric substrate comprising:
a resin matrix component; and
ceramic filler component,
wherein the ceramic filler component comprises a first filler material, and
wherein a particle size distribution of the first filler material comprises:
a D₁₀ of at least about 0.5 microns and not greater than about 1.6 microns,
a D₅₀ of at least about 0.8 microns and not greater than about 2.7 microns, and
a D₉₀ of at least about 1.5 microns and not greater than about 4.7 microns.

2. The dielectric composite of claim 1, wherein the reinforcement fabric layer comprises a glass fabric material.

3. The dielectric composite of claim 1, wherein the reinforcement fabric layer comprises E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof.

4. The dielectric composite of claim 1, wherein the reinforcement fabric layer comprises a woven fabric of fibrous material.

5. The dielectric composite of claim 4, wherein the fibrous material comprises E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof.

6. The dielectric composite of claim 1, wherein the reinforcement fabric layer comprises a non-woven fabric of fibrous material.

7. The dielectric composite of claim 6, wherein the fibrous material comprises E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof.

8. The dielectric composite of claim 1, wherein the reinforcement fabric layer has a thickness of at least about 4 microns.

9. The dielectric composite of claim 1, wherein the reinforcement fabric layer has a thickness of not greater than about 1 mm.

10. The dielectric composite of claim 1, wherein the dielectric composite further comprises an adhesive layer between the reinforcement fabric and the dielectric substrate.

11. The dielectric composite of claim 10, wherein the adhesive layer comprises PFA, FEP or any combination thereof.

12. The dielectric composite of claim 10, wherein the adhesive layer has a thickness of at least about 0.1 microns.

13. The dielectric composite of claim 10, wherein the adhesive layer has a thickness of not greater than about 25 microns.

14. A dielectric composite comprising a dielectric substrate overlying a reinforcement fabric layer, wherein the dielectric substrate comprising:
a resin matrix component; and
a ceramic filler component,
wherein the ceramic filler component comprises a first filler material, and wherein the first filler material further comprises a mean particle size of not greater than about 10 microns, and a particle size distribution span (PSDS) of not greater than about 5, where PSDS is equal to (D₉₀−D₁₀)/D₅₀, where D₉₀ is equal to a D₉₀ particle size distribution measurement of the first filler material, D₁₀ is equal to a D₁₀ particle size distribution measurement of the first filler material, and D₅₀ is equal to a D₅₀ particle size distribution measurement of the first filler material.

15. The dielectric composite of claim 14, wherein the reinforcement fabric layer comprises a glass fabric material.

16. The dielectric composite of claim 15, wherein the reinforcement fabric layer comprises E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof.

17. The dielectric composite of claim 14, wherein the reinforcement fabric layer comprises a woven fabric of fibrous material.

18. The dielectric composite of claim 17, wherein the fibrous material comprises E-glass fabric, NE-glass fabric, S-glass fabric, L-glass fabric, D-glass fabric, quartz glass fabric, aromatic polyamide fabric (i.e., Kevlar fabric), polytetrafluoroethylene (PTFE) fabric, polyester fabric, liquid crystal polymer (LCP) fabric, or any combination thereof.

19. The dielectric composite of claim 14, wherein the reinforcement fabric layer comprises a non-woven fabric of fibrous material.

20. A dielectric composite comprising a dielectric substrate overlying a reinforcement fabric layer, wherein the dielectric substrate comprising:
a resin matrix component; and
a ceramic filler component,
wherein the ceramic filler component comprises a first filler material, and
wherein the first filler material further comprises a mean particle size of at not greater than about 10 microns, and an average surface area of not greater than about 8 m²/g.
